(19) United States
(12) Patent Application Publication
(10) Pub. No.: US 2025/0248279 A1
(43) Pub. Date: Jul. 31, 2025

(54) TRANSPARENT LAMINATE, IMAGE DISPLAY DEVICE, AND FLEXIBLE DEVICE

(71) Applicant: DAICEL CORPORATION, Osaka (JP)

(72) Inventors: Masashi YOKOYAMA, Tokyo (JP); Tsubasa MIKI, Tokyo (JP)

(73) Assignee: DAICEL CORPORATION, Osaka (JP)

(21) Appl. No.: 19/034,079

(22) Filed: Jan. 22, 2025

(30) Foreign Application Priority Data
Jan. 26, 2024 (JP) 2024-010563

(51) Int. Cl. H10K 59/80; B32B 17/10; H10K 102/00

(52) U.S. Cl. CPC H10K 59/873; B32B 17/10; B32B 2255/26; B32B 2255/28; B32B 2307/412; B32B 2307/536; B32B 2307/54; B32B 2307/546; B32B 2307/7376; B32B 2457/206; H10K 2102/311

(57) ABSTRACT

Problem

To provide a transparent laminate that exhibits excellent bendability while having a high hardness.

Solution

A transparent laminate according to the present disclosure includes a substrate and a hard coat layer laminated on at least one surface of the substrate. The transparent laminate has a pencil hardness of H or higher at a load of 750 g on a surface of the hard coat layer. The transparent laminate has a minimum bendable radius of 1.5 mm or less when the transparent laminate is subjected to a cylindrical mandrel test in such a manner that the surface of the hard coat layer of the transparent laminate is bent into a concave shape. The transparent laminate has a ratio of an indentation elastic modulus to an indentation hardness (indentation elastic modulus/indentation hardness) of 6.0 or greater in a microhardness test.

### TECHNICAL FIELD

The present disclosure relates to a transparent laminate, an image display device, and a flexible device.

### BACKGROUND ART

To further improve the portability of personal digital assistants such as smartphones and tablets, there is an increasing demand for foldable devices such as foldable displays and touch screens. In a known configuration, a hard coat layer is used as a cover material on the outermost surface of the display of such a foldable device. In addition, the hard coat layer is required to have a high hardness in order to prevent the occurrence of scratches and indentations while exhibiting transparency and aesthetics. An example of an invention that uses this type of hard coat layer having a high hardness is the invention disclosed in Patent Document 1.

### CITATION LIST

### Patent Document

Patent Document 1: JP 2022-081716 A

### SUMMARY OF INVENTION

### Technical Problem

However, the problem with the hard coat layer of Patent Document 1 is that when the hardness is increased, the bendability (flexibility) decreases, and cracks are easily generated in the hard coat layer or the substrate.

Therefore, the object of the present disclosure is to solve the problems described above, and provide a transparent laminate that exhibits excellent bendability while having a high hardness.

### Solution to Problem

The inventors of the present disclosure have discovered that a transparent laminate including a substrate and a hard coat layer laminated on at least one surface of the substrate exhibits excellent bendability while maintaining a high hardness as long as the surface of the hard coat layer satisfies specific ranges for pencil hardness, minimum bendable radius, and a ratio of the indentation elastic modulus to the indentation hardness in microhardness measurements. The present disclosure has been completed based on these findings.

That is, the present disclosure provides a transparent laminate including a substrate and a hard coat layer laminated on at least one surface of the substrate, wherein the transparent laminate is characterized in that the transparent laminate has a pencil hardness of H or higher at a load of 750 g on a surface of the hard coat layer, the transparent laminate has a minimum bendable radius of 1.5 mm or less when the transparent laminate is subjected to a cylindrical mandrel test with the surface of the hard coat layer of the transparent laminate being concave, and the transparent laminate has a ratio of an indentation elastic modulus to an indentation hardness (indentation elastic modulus/indentation hardness) of 6.0 or greater in a microhardness test.

When the pencil hardness is H or higher, the minimum bendable radius is 1.5 mm or less, and the ratio of the indentation elastic modulus to the indentation hardness is 6.0 or greater, the hard coat surface exhibits excellent bendability while having a high hardness.

The haze of the hard coat layer in the transparent laminate is preferably 1.0% or less.

Moreover, in the transparent laminate, preferably, the hard coat layer is a cured product of a curable composition containing one or more curable compounds, and the curable composition contains, as the one or more curable compounds, an aliphatic compound having two or more cationically polymerizable groups per molecule.

The curable composition preferably contains, as the one or more curable compounds, a polyorganosilsesquioxane.

The curable composition preferably contains, as the one or more curable compounds, two or more types of the aliphatic compounds. By having the above configurations, the transparent laminate can easily achieve a high hardness as well as bendability.

The curable composition preferably further includes a curing catalyst.

The curing catalyst preferably includes a cationic polymerization initiator.

The curing catalyst preferably includes a radical polymerization initiator.

In addition, the transparent laminate preferably does not contain a compound corresponding to a PFAS in the hard coat layer.

The transparent laminate preferably further includes a surface protection film on at least one surface thereof.

In the transparent laminate, preferably, the hard coat layer is provided on one surface of the substrate and a tacky adhesive layer is provided on the other surface thereof.

The substrate is preferably glass having a thickness of from 30 to 100 μm.

The present disclosure also provides an image display device including the transparent laminate described above.

The image display device is preferably a flexible display.

The image display device is preferably an organic electroluminescent display device.

The present disclosure also provides a flexible device including the image display device described above.

### Advantageous Effects of Invention

The transparent laminate according to an embodiment of the present disclosure exhibits excellent bendability while having a high hardness. Therefore, the transparent laminate can be suitably used in an image display device such as a flexible display.

### DESCRIPTION OF EMBODIMENTS

Note that in the present disclosure, the term “compound corresponding to a PFAS” is a generic term for perfluoroalkyl compounds and polyfluoroalkyl compounds.

### Transparent Laminate

A transparent laminate according to an embodiment of the present disclosure includes a substrate and a hard coat layer laminated on at least one surface of the substrate. The transparent laminate has a pencil hardness of H or higher at a load of a 750 g on a surface of the hard coat layer. The transparent laminate has a minimum bendable radius of 1.5 mm or less when the transparent laminate is subjected to a cylindrical mandrel test with the surface of the hard coat layer of the transparent laminate being concave. The transparent laminate has a ratio of an indentation elastic modulus to an indentation hardness (indentation elastic modulus/indentation hardness) of 6.0 or greater in a microhardness test. The transparent laminate according to an embodiment of the present disclosure having the above-described configuration has a high hardness and excellent bendability.

The transparent laminate may have other layers in addition to the substrate and the hard coat layer. Examples of the other layers include a surface protection film, a tacky adhesive layer, an undercoat layer for bonding the substrate and the hard coat layer, an antireflection layer, an anti-glare layer, a fingerprint-resistant layer, an antifouling layer, a scratch and fingerprint-resistant layer, an antibacterial layer, a bonding layer, and a polarizing layer. Here, the other layers may be formed on only one surface (one side) of the substrate, or may be formed on both surfaces (both sides) of the substrate. In addition, when the other layers are formed on both surfaces of the substrate, the same layers may be laminated on each surface, or layers having different thicknesses or compositions may be laminated on the surfaces of the substrate.

The transparent laminate has a pencil hardness of H or higher, preferably 2H or higher, on the surface of the hard coat layer, as measured in accordance with JIS K5600 5-4. When the pencil hardness is H or higher, the surface hardness becomes sufficient, and abrasion resistance is easily exhibited. Note that when the hard coat layer is laminated on both surfaces of the transparent laminate, the above range need only be satisfied on at least one surface.

When the transparent laminate is subjected to a cylindrical mandrel test performed in accordance with JIS K5600 5-1 in such a manner that the transparent laminate is bent with the surface of the hard coat layer being concave, the minimum bendable diameter at which cracking does not occur is in a range of 1.5 mm or less. When the minimum bendable radius is 1.5 mm or less, sufficient bendability can be exhibited. Note that in a case in which the hard coat layer is laminated on both surfaces of the transparent laminate, the abovementioned range for the minimum bendable radius need only be satisfied on at least one surface, and preferably, the hard coat layer having the pencil hardness of H or higher satisfies the minimum bendable radius described above.

In microhardness measurements of the hard coat layer surface, the transparent laminate preferably has an indentation elastic modulus of from 400 to 4000 MPa, more preferably from 600 to 3500 MPa, and even more preferably from 800 to 3000 MPa. When the indentation elastic modulus is 400 MPa or greater, the surface hardness tends to be excellent. When the indentation elastic modulus is 4000 MPa or less, both elongation and bendability can be achieved while rigidity is maintained.

In microhardness measurements of the hard coat layer surface, the transparent laminate preferably has an indentation hardness of from 50 to 500 MPa, more preferably from 70 to 450 MPa, and even more preferably from 90 to 400 MPa. When the indentation hardness is 50 MPa or greater, the surface hardness of the transparent laminate increases, and indentations and scratches are less likely to occur. In addition, when the indentation hardness is 500 MPa or less, the transparent laminate tends to exhibit excellent flexibility and excellent bendability. When the hard coat layer is laminated on both surfaces of the transparent laminate, the above range need only be satisfied on at least one surface, and preferably, a hard coat layer having a pencil hardness of H or higher satisfies the above indentation hardness.

The transparent laminate has a ratio of the indentation elastic modulus to the indentation hardness (indentation elastic modulus/indentation hardness) of 6.0 or greater, preferably 6.5 or greater, and more preferably 7.0 or greater. When the abovementioned ratio is 6.0 or greater, a transparent laminate that exhibits excellent bendability while maintaining sufficient surface hardness can be produced. The upper limit of the ratio thereof is not particularly limited, but is preferably 80.0 or less in order to achieve sufficient surface hardness.

The thickness of the transparent laminate is preferably from 10 to 500 μm, more preferably from 30 to 400 μm, and particularly preferably from 50 to 300 μm. When the thickness of the transparent laminate is 10 μm or greater, sufficient surface hardness is easily achieved. In addition, when the thickness is 500 μm or less, sufficient bendability is easily exhibited.

### Substrate

As the substrate in the transparent laminate according to an embodiment of the present disclosure, a known or commonly used substrate can be used, such as a plastic substrate, a metal substrate, a ceramic substrate, a semiconductor substrate, a glass substrate, a paper substrate, a wood substrate (wooden substrate), and a substrate having a surface that is a coated surface. Among these, from the viewpoint of exhibiting transparency, a glass substrate and a plastic substrate are preferable, and a glass substrate is particularly preferable. The substrate may have a single-layer structure or a multi-layer structure, and may be composed of one type of material or two or more types of materials.

The glass substrate may be chemically strengthened from the viewpoints of improving strength against cracking when the glass is made thin and configuring a panel that is durable enough for practical use. Moreover, the glass substrate is preferably subjected to end face treatment from the viewpoint of making a substrate with sufficient strength. In addition, in order to improve abrasion resistance, smoothness, and strength against cracking, a treated layer or a coating film may be formed on any surface.

The thickness of the substrate is, for example, preferably from 30 to 100 μm, more preferably from 40 to 95 μm, and still more preferably from 50 to 90 μm. When the thickness of the glass substrate is 30 μm or greater, the glass substrate can easily exhibit sufficient strength as a substrate. In addition, when the thickness of the glass substrate is 100 μm or less, the glass substrate can easily exhibit bendability.

The transparent laminate may have a surface protection film. The surface protection film protects the surface of the hard coat layer, and the transparent laminate preferably has a surface protection film on at least one surface thereof. When the hard coat layer is formed on both surfaces of the substrate, the surface protection film may be provided on both surfaces of the transparent laminate.

The surface protection film is not particularly limited, and a well-known or commonly used surface protection film can be used. For example, a film having a tacky adhesive agent layer on the surface of a plastic film can be used. Examples of the plastic film include plastic films formed from plastic materials such as polyesters (e.g., polyethylene terephthalate, polyethylene naphthalate), polyolefins (e.g., polyethylene, polypropylene, cyclic polyolefins), polystyrenes, acrylic resins, polycarbonates, epoxy resins, fluororesins, silicone resins, diacetate resins, triacetate resins, polyarylates, polyvinyl chlorides, polysulfones, polyethersulfones, polyether ether imides, polyimides, and polyamides. Examples of the tacky adhesive agent layer include a tacky adhesive agent layer formed from one or more types of well-known and commonly used tacky adhesives such as acrylic tacky adhesives, silicone-based tacky adhesives, natural rubber-based tacky adhesives, synthetic rubber-based tacky adhesives, ethylene-vinyl acetate copolymer-based tacky adhesives, ethylene-(meth)acrylate copolymer-based tacky adhesives, styrene-isoprene block copolymer-based tacky adhesives, and styrene-butadiene block copolymer-based tacky adhesives. The tacky adhesive agent layer may contain various additives (for example, antistatic agents, and slip agents). Note that the plastic film and the tacky adhesive agent layer each may have a single layer configuration or may have a multilayer (multiple layer) configuration. In addition, the thickness of the surface protection film is not particularly limited, and can be appropriately selected.

As the surface protection film, commercially available products can be procured from the marketplace including, for example, “Sunytect” (trade name) series (available from Sun A. Kaken Co., Ltd.), “E-MASK” (trade name) series (available from Nitto Denko Corporation), “Mastack” (trade name) series (available from Fujimori Kogyo Co., Ltd.), “Hitalex” (trade name) series (available from Hitachi Chemical Co., Ltd.), and “Alphan” (trade name) series (available from Oji F-Tex Co., Ltd.).

Further, the transparent laminate may have a tacky adhesive layer. In the transparent laminate, the tacky adhesive layer is preferably laminated on the surface of the substrate opposite the surface on which the hard coat layer is laminated. That is, when the transparent laminate has the tacky adhesive layer, preferably, the hard coat layer is provided on one surface of the substrate, and the tacky adhesive layer is provided on the other surface of the substrate. In addition, the transparent laminate more preferably has the tacky adhesive layer on one surface.

As the tacky adhesive constituting the tacky adhesive layer, a tacky adhesive similar to the tacky adhesive exemplified with regard to the surface protection film can be used. Among these, from the viewpoint of achieving good transparency and sufficient tacky adhesive strength even when the tacky adhesive layer is thin, an acrylic tacky adhesive and a silicone tacky adhesive are preferable, and an acrylic tacky adhesive is particularly preferable. Note that a single type of the tacky adhesive may be used alone, or two or more types may be used in combination.

The thickness of the tacky adhesive layer is, for example, from 0.1 to 50 μm, preferably from 1 to 45 μm, more preferably from 2 to 40 μm, and even more preferably from 5 to 35 μm.

The tacky adhesive layer can be produced by applying the tacky adhesive to at least one surface of the substrate and curing the tacky adhesive.

Further, the transparent laminate may have an undercoat layer. In particular, when the transparent laminate has a glass substrate, a problem in the adhesiveness between the substrate and the hard coat layer may occur, and thus an undercoat layer is preferably provided between the glass substrate and the hard coat layer.

The material of the undercoat layer is not particularly limited, and examples thereof include a resin. Examples of the resin include (meth)acrylic resins, urethane resins, (meth)acrylic urethane copolymers, vinyl chloride-vinyl acetate copolymers, polyesters, butyral resins, chlorinated polypropylene, chlorinated polyethylene, epoxy resins, and silicone resins. Of these resins, a single type may be used alone, or two or more types may be used in combination.

The thickness of the undercoat layer is preferably from 0.1 to 30 μm, and more preferably 1 to 20 μm. When the thickness of the undercoat layer is within the above range, the undercoat layer exhibits adherence to the substrate, as well as helps the surface hardness of the surface of the hard coat layer to improve when the hard coat layer is further laminated.

The undercoat layer can be produced by applying the abovementioned resin to at least one surface of the substrate and then curing the resin.

A general coating method can be used as a method for forming the undercoat layer. For example, a known method such as a dipping, roll coating, gravure coating, reverse coating, air knife coating, comma coating, die coating, screen printing, spray coating, gravure offset, and organic vapor deposition can be used. An example of the curing treatment is irradiation with light using, for example, a mercury lamp, a xenon lamp, a carbon arc lamp, a metal halide lamp, sunlight, an electron beam source, a laser light source, or an LED light source. The irradiation is preferably implemented with a cumulative irradiation amount in a range of, for example, from 300 to 10000 mJ/cm². In addition, a film coated in advance onto another substrate by the above-described forming method may be transferred to the substrate using a transfer method such as tacky adhesive material transfer, thermal transfer, or UV transfer.

After completion of the irradiation with light, an annealing treatment is preferably implemented to remove internal strain, and for example, heating is preferably implemented at a temperature of from 100 to 200° C. for about 30 minutes to 1 hour.

### Hard Coat Layer

In the transparent laminate, the hard coat layer may be formed on only one surface (one side) of the substrate, or the hard coat layer may be formed on both surfaces (both sides) of the substrate. However, in a case in which the transparent laminate has the abovementioned tacky adhesive layer, the hard coat layer is preferably formed on only one surface of the substrate. Note that when the hard coat layer is formed on both surfaces of the substrate, the physical property values of the hard coat layer described above and below need only be satisfied on at least one surface. Furthermore, the same hard coat layer may be laminated on both surfaces of the substrate, or hard coat layers having different thicknesses or compositions may be laminated on respective surfaces of the substrate. In addition, the hard coat layer may be formed on one surface of the substrate, and another layer described above may be formed on the other surface. However, from the viewpoint of suppressing the occurrence of cracks, preferably, the hard coat layer is formed on at least one surface of the substrate, and the hard coat layer or the other layer is formed on the other surface.

The hard coat layer is preferably formed of a cured product of a curable composition containing one or more curable compounds. That is, the curable composition preferably contains one or more types of curable compounds. A single type of curable compound may be used alone, or two or more types may be used in combination.

The curable composition preferably contains a polyorganosilsesquioxane as the curable compound. When the curable composition contains the polyorganosilsesquioxane, the curable composition is less likely to shrink when cured, and thus a hard coat layer can have a higher hardness and more excellent scratch resistance. Examples of the polyorganosilsesquioxane include radically polymerizable polyorganosilsesquioxanes and cationically polymerizable polyorganosilsesquioxanes. Among these, the polyorganosilsesquioxane is preferably a cationically polymerizable polyorganosilsesquioxane, and the cationically polymerizable polyorganosilsesquioxane is more preferably a photocationically polymerizable polyorganosilsesquioxane.

The radically polymerizable polyorganosilsesquioxane has a radically polymerizable functional group in the molecule. Examples of the “radically polymerizable functional group” include a (meth)acryloyl group, a (meth)acrylamide group, a vinyl group, and a vinylthio group.

The cationically polymerizable polyorganosilsesquioxane has a cationically polymerizable functional group in the molecule. Examples of the “cationically polymerizable functional group” include an epoxy group, an oxetane group, a vinyl ether group, and a vinyl phenyl group. Among these, an epoxy group is preferable from the viewpoint of further increasing the surface hardness of the hard coat layer.

The group containing an epoxy group is not particularly limited, and examples thereof include well-known or commonly-used groups having an oxirane ring. However, in terms of curability of the curable composition and heat resistance of the hard coat layer, a group represented by Formula (1a) below, a group represented by Formula (1b) below, a group represented by Formula (1c) below, and a group represented by Formula (1d) below are preferred, a group represented by Formula (1a) below and a group represented by Formula (1c) below are more preferred, and a group represented by Formula (1a) below is even more preferred.

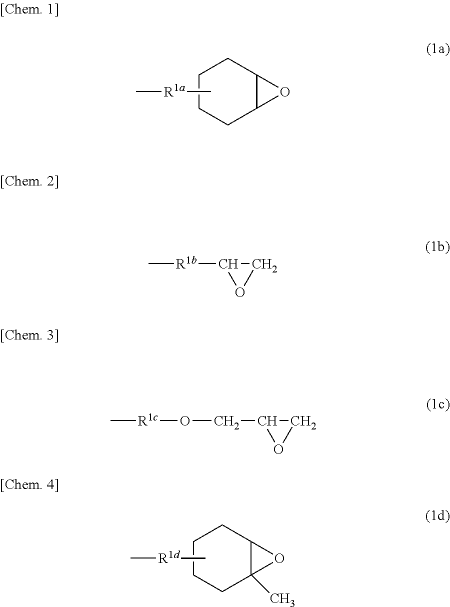

In Formula (1a) above, R^{1a} represents a linear or branched alkylene group. Examples of the linear or branched alkylene group include linear or branched alkylene groups having from 1 to 10 carbons, such as a methylene group, a methyl methylene group, a dimethyl methylene group, an ethylene group, a propylene group, a trimethylene group, a tetramethylene group, a pentamethylene group, a hexamethylene group, and a decamethylene group. Among these, from the viewpoint of the curability of the curable composition, R^{1a} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1b) above, R^{1b} represents a linear or branched alkylene group, and examples thereof include the same groups listed as examples of R^{1a}. Among these, from the viewpoint of the curability of the curable composition, R^{1b} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1c) above, R^{1c} represents a linear or branched alkylene group, and examples thereof include the same groups listed as examples of R^{1a}. Among these, from the viewpoint of the curability of the curable composition, R^{1c} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1d) above, R^{1d} represents a linear or branched alkylene group, and examples thereof include the same groups listed as examples of R^{1a}. Among these, from the viewpoint of the curability of the curable composition, R^{1d} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

R¹ in Formula (1) is particularly preferably a group represented by Formula (1a) above in which R^{1a} is an ethylene group (especially, a 2-(3,4-epoxycyclohexyl)ethyl group).

Examples of the polyorganosilsesquioxane include compounds having a constituent unit represented by Formula (1) below.

[R¹SiO_{3/2}] (1)

The constituent unit represented by Formula (1) above is a silsesquioxane constituent unit (so-called T unit) generally represented by [RSiO_{3/2}]. Here, R in the formula described above represents a hydrogen atom or a monovalent organic group, and the same shall apply hereafter. The constituent unit represented by Formula (1) above is formed by a hydrolysis and condensation reaction of a corresponding hydrolyzable trifunctional silane compound. Note that in the present specification, a compound having a constituent unit represented by the above Formula (1) may be referred to as a “silsesquioxane (X)”. R¹ in Formula (1) represents a group (monovalent group) containing the above-described cationically polymerizable functional group.

The silsesquioxane (X) may include only one type of constituent unit represented by Formula (1) above or may include two or more types of constituent units represented by Formula (1) above.

The silsesquioxane (X) may also include, as the silsesquioxane constituent unit [RSiO_{3/2}], a constituent unit represented by Formula (2) below, in addition to the constituent unit represented by Formula (1) above.

[R²SiO_{3/2}] (2)

The constituent unit represented by Formula (2) above is a silsesquioxane constituent unit (T unit) generally represented by [RSiO_{3/2}]. That is, the constituent unit represented by Formula (2) above is formed by a hydrolysis and condensation reaction of a corresponding hydrolyzable trifunctional silane compound.

R² in Formula (2) represents a substituted or unsubstituted aryl group, a substituted or unsubstituted aralkyl group, a substituted or unsubstituted cycloalkyl group, or a substituted or unsubstituted alkyl group. Examples of the aryl group include a phenyl group, a tolyl group, and a naphthyl group. Examples of the aralkyl group include a benzyl group and a phenethyl group. Examples of the cycloalkyl group include a cyclobutyl group, a cyclopentyl group, and a cyclohexyl group. Examples of the alkyl group include linear or branched alkyl groups, such as a methyl group, an ethyl group, a propyl group, an n-butyl group, an isopropyl group, an isobutyl group, an s-butyl group, a t-butyl group, and an isopentyl group.

Examples of the substituted aryl group, the substituted aralkyl group, the substituted cycloalkyl group, and the substituted alkyl group described above include groups in which some or all of hydrogen atoms or the main chain skeleton in each of the aryl groups, the aralkyl groups, the cycloalkyl groups, and the alkyl groups described above are substituted with at least one selected from the group consisting of an alkyl group (in particular, a linear or branched alkyl group having from 1 to 10 carbons), an ether group, an ester group, a carbonyl group, a siloxane group, a halogen atom (such as a fluorine atom), a mercapto group, an amino group, and a hydroxyl group.

Among these, R² is preferably a substituted or unsubstituted aryl group or a substituted or unsubstituted alkyl group, more preferably a substituted or unsubstituted aryl group, and even more preferably a phenyl group.

A ratio of each above-described silsesquioxane constituent unit (the constituent unit represented by Formula (1) and the constituent unit represented by Formula (2)) in the silsesquioxane (X) can be appropriately adjusted by the composition of the raw materials (hydrolyzable trifunctional silanes) for forming these constituent units.

Among these constituent units, the silsesquioxane (X) preferably contains at least a constituent unit represented by the above Formula (1) in which R¹ is a group containing an alicyclic epoxy group and a constituent unit represented by the above Formula (2) in which R² is an aryl group which may have a substituent. In this case, the surface hardness, flexibility, processability, and flame retardancy of the hard coat layer tend to be more excellent.

In addition to the constituent unit represented by Formula (1) above and the constituent unit represented by Formula (2) above, which are T units, the silsesquioxane (X) may further contain at least one siloxane constituent unit selected from the group consisting of a constituent unit represented by [R₃SiO_{1/2}] (so-called M unit), a constituent unit represented by [R₂SiO_{2/2}] (so-called D unit), and a constituent unit represented by [SiO_{4/2}] (so-called Q unit). Note that examples of R in the M unit and the D unit include the same groups as those exemplified as R¹ in the constituent unit represented by Formula (1) and those exemplified as R² in the constituent unit represented by Formula (2). An example of a silsesquioxane constituent unit other than the constituent unit represented by Formula (1) above and the constituent unit represented by Formula (2) above include a constituent unit represented by Formula (3) below.

[HSiO_{3/2}] (3)

The silsesquioxane (X) includes a constituent unit (T3 form) represented by Formula (I) below. The silsesquioxane (X) may further include a constituent unit (T2 form) represented by Formula (II) below.

[R^{a}SiO^{3/2}] (I)

[R^{b}SiO_{2/2}(OR^{c})] (II)

The constituent unit represented by Formula (I) above is represented by Formula (I′) below in more detail. Furthermore, the constituent unit represented by Formula (II) above is represented by Formula (II′) below in more detail. Three oxygen atoms bonded to the silicon atom illustrated in the structure represented by formula (I′) below are each bonded to another silicon atom (a silicon atom not illustrated in formula (I′)). On the other hand, two oxygen atoms located above and below the silicon atom illustrated in the structure represented by Formula (II′) below are each bonded to another silicon atom (a silicon atom not illustrated in Formula (II′)). That is, both T3 form and T2 form are constituent units (T units) formed by a hydrolysis and condensation reaction of a corresponding hydrolyzable trifunctional silane compound.

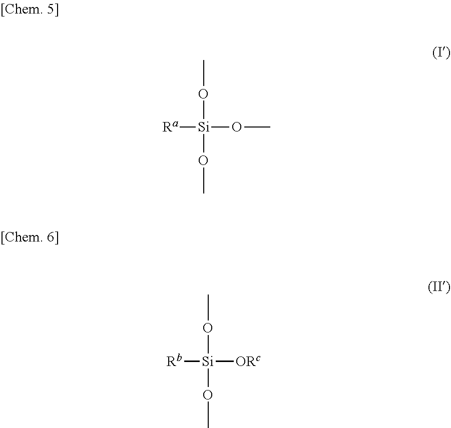

R^{a} in Formula (I) above (likewise, R^{a} in Formula (F)) and R^{b} in Formula (II) above (likewise, R^{b} in Formula (IF)) each represent a group containing a cationically polymerizable functional group, a substituted or unsubstituted aryl group, a substituted or unsubstituted aralkyl group, a substituted or unsubstituted cycloalkyl group, a substituted or unsubstituted alkyl group, or a hydrogen atom. Specific examples of R^{a} and R^{b} include the same examples as those given for R¹ in Formula (1) above and R² in Formula (2) above. R^{a} in Formula (I) and R^{b} in Formula (II) are each a group derived from a group (a group other than an alkoxy group and a halogen atom) bonded to a silicon atom in the hydrolyzable trifunctional silane compound used as a raw material of the silsesquioxane (X), or, in a case in which the cationically polymerizable functional group is an epoxy group, a group produced by epoxidizing a group (a group other than an alkoxy group and a halogen atom) bonded to a silicon atom in the hydrolyzable trifunctional silane compound used as a raw material of the silsesquioxane (X).

R^{c} in Formula (II) above (likewise, R^{c} in Formula (If)) represents a hydrogen atom or an alkyl group having from 1 to 4 carbons. Examples of the alkyl group having from 1 to 4 carbons include a linear or branched alkyl group having from 1 to 4 carbons, such as a methyl group, an ethyl group, a propyl group, an isopropyl group, a butyl group, and an isobutyl group. Among these, a methyl group and an ethyl are preferable, and a methyl group is more preferable. The alkyl group of R^{c} in Formula (II) is typically derived from an alkyl group that forms an alkoxy group in a hydrolyzable silane compound used as a raw material for the silsesquioxane (X).

In the silsesquioxane (X), a molar ratio of the constituent units represented by Formula (I) above (T3 forms) to the constituent units represented by Formula (II) above (T2 forms), [constituent units represented by Formula (I)/constituent units represented by Formula (II)](may be described as “T3 form/T2 form”), is not particularly limited, but is preferably 5 or greater, more preferably from 5 to 20, even more preferably from 5 to 18, yet even more preferably from 6 to 16, still more preferably from 7 to 15, and particularly preferably from 8 to 14. When the above [(T3 form)/(T2 form)] molar ratio is 5 or greater, the surface hardness of the hard coat layer tends to further improve.

The above molar ratio [T3 form/T2 form] in the silsesquioxane (X) can be determined, for example, through ²⁹Si-NMR spectrum measurements. In the ²⁹Si-NMR spectrum, the silicon atoms in the constituent units represented by Formula (I) above (T3 forms) and the silicon atoms in the constituent units represented by Formula (II) above (T2 forms) exhibit signals (peaks) at different positions (chemical shifts), and thus the above-mentioned [T3 form/T2 form] molar ratio can be determined by calculating the integration ratio of these peaks. Specifically, for example, when the silsesquioxane (X) includes a constituent unit represented by Formula (1) above in which R¹ is a 2-(3,4-epoxycyclohexyl)ethyl group, the signal of the silicon atom in the structure (T3 form) represented by Formula (I) above appears in a range from −64 to −70 ppm, and the signal of the silicon atom in the structure (T2 form) represented by Formula (II) above appears in a range from −54 to −60 ppm. Thus, in this case, the above molar ratio [T3 form/T2 form] can be determined by calculating the integration ratio of the signal (T3 form) in the range from −64 to −70 ppm and the signal (T2 form) in the range from −54 to −60 ppm.

The ²⁹Si-NMR spectrum of the silsesquioxane (X) can be measured, for example, with the following instrument and under the following conditions.
Measuring instrument: “JNM-ECA500NMR” (trade name, available from JEOL Ltd.)
Solvent: deuterochloroform
Cumulative number of times: 1800
Measurement temperature: 25° C.

When the above molar ratio [T3 form/T2 form] of the silsesquioxane (X) is 5 or greater, this means that a certain amount or more of the T2 forms are present relative to the T3 forms in the silsesquioxane (X). Examples of the T2 form include a constituent unit represented by Formula (4) below, a constituent unit represented by Formula (5) below, and a constituent unit represented by Formula (6) below. R¹ in Formula (4) below and R² in Formula (5) below are the same as the R¹ in Formula (1) above and the R² in Formula (2) above, respectively. R^{c} in Formulae (4) to (6) below represents a hydrogen atom or an alkyl group having from 1 to 4 carbons, in the same manner as R^{c} in Formula (II).

[R¹SiO_{2/2}(OR^{c})] (4)

[R²SiO_{2/2}(OR^{c})] (5)

[HSiO_{2/2}(OR^{c})] (6)

The polyorganosilsesquioxane (in particular, the silsesquioxane (X)) may be a silsesquioxane having a cage shape (cage-type silsesquioxane). Examples of the cage-type silsesquioxane include a complete cage-type silsesquioxane and an incomplete cage-type silsesquioxane, and among these, an incomplete cage-type silsesquioxane is preferable.

Typically, a complete cage-type silsesquioxane is a polyorganosilsesquioxane constituted of a T3 form only, and no T2 form is present in the molecule. That is, a silsesquioxane having the above molar ratio [T3 form/T2 form] of 5 or greater and having one inherent absorption peak near 1100 cm¹ in an FT-IR spectrum as described later suggests the inclusion of an incomplete cage-type silsesquioxane structure.

Whether the silsesquioxane (X) has a cage-type (incomplete cage-type) silsesquioxane structure can be confirmed by the FT-IR spectrum [refer to R. H. Raney, M. Itoh, A. Sakakibara and T. Suzuki, Chem. Rev. 95, 1409 (1995)]. Specifically, if the silsesquioxane (X) has one inherent absorption peak near 1100 cm⁻¹ without having inherent absorption peaks near 1050 cm⁻¹ and 1150 cm⁻¹ in the FT-IR spectrum, the silsesquioxane (X) can be identified as having a cage-type (incomplete cage-type) silsesquioxane structure. In contrast, a silsesquioxane (X) having inherent absorption peaks near 1050 cm⁻¹ and near 1150 cm⁻¹ each in the FT-IR spectrum is typically identified as having a ladder-type silsesquioxane structure. The FT-IR spectrum of the silsesquioxane (X) can be measured, for example, with the following instrument and conditions.
Measuring instrument: trade name “FT-720” (available from Horiba, Ltd.)
Measurement method: transmission method
Resolution: 4 cm⁻¹
Measurement wavenumber range: from 400 to 4000 cm⁻
Cumulative number of times: 16

The proportion (total amount) of the constituent unit having the cationically polymerizable functional group (for example, the constituent unit represented by Formula (1) above, the constituent unit represented by Formula (4) above, and the like) relative to a total amount (100 mol %) of siloxane constituent units [all siloxane constituent units; total amount of M units, D units, T units, and Q units] in the polyorganosilsesquioxane is not particularly limited, but is preferably 50 mol % or greater (for example, from 50 to 100 mol %), more preferably from 55 to 100 mol %, even more preferably from 65 to 99.9 mol %, yet even more preferably from 80 to 99 mol %, and particularly preferably from 90 to 98 mol %. When the above proportion is set to 50 mol % or greater, the curability of the curable composition improves, and the surface hardness of the hard coat layer significantly increases. In addition, the proportion of each siloxane constituent unit in the polyorganosilsesquioxane can be calculated, for example, from the raw material composition, through NMR spectrum measurements, or the like.

The proportion of the constituent unit (T3 form) represented by Formula (I) above relative to the total amount (100 mol %) of siloxane constituent units [all siloxane constituent units; total amount of M units, D units, T units, and Q units] in the silsesquioxane (X) is not particularly limited, but is preferably 50 mol % or greater, more preferably from 60 to 99 mol %, even more preferably from 70 to 98 mol %, yet even more preferably from 80 to 95 mol %, and particularly preferably from 85 to 92 mol %. When the proportion of the constituent unit of the T3 form is 50 mol % or greater, the surface hardness of the hard coat layer tends to further improve. This is presumed to be due to a facilitation of the formation of an incomplete cage shape having an appropriate molecular weight.

The proportion (total amount) of the constituent unit represented by Formula (2) above and the constituent unit represented by Formula (5) above relative to the total amount (100 mol %) of siloxane constituent units [all siloxane constituent units; total amount of M units, D units, T units, and Q units] in the silsesquioxane (X) is not particularly limited, but is preferably from 0 to 50 mol %, more preferably from 0 to 40 mol %, even more preferably from 0 to 30 mol %, and particularly preferably from 1 to 15 mol %. When the above ratio is set to 50 mol % or less, the proportion of the constituent unit having a cationically polymerizable functional group can be relatively increased, and thus such a ratio tends to improve the curability of the curable composition and further increase the surface hardness of the hard coat layer.

The proportion (total amount) of the constituent unit represented by Formula (I) above and the constituent unit represented by Formula (II) above (in particular, the proportion of the total of T3 forms and T2 forms) relative to the total amount (100 mol %) of siloxane constituent units [all siloxane constituent units; total amount of M units, D units, T units, and Q units] in the silsesquioxane (X) is not particularly limited, but is preferably 60 mol % or greater (for example, from 60 to 100 mol %), more preferably from 70 mol % or greater, even more preferably from 80 mol % or greater, and particularly preferably from 90 mol % or greater. When the above proportion is 60 mol % or greater, the surface hardness of the hard coat layer tends to further improve. This is presumed to be due to a facilitation of the formation of an incomplete cage shape having an appropriate molecular weight. In particular, the proportion (total amount) of the constituent unit represented by the Formula (1) above, the constituent unit represented by the Formula (2) above, the constituent unit represented by the Formula (4) above, and the constituent unit represented by the Formula (5) above is preferably within the above range.

The number average molecular weight (Mn) of the silsesquioxane (X) determined by gel permeation chromatography calibrated with polystyrene is not particularly limited, but is preferably from 1000 to 3000, more preferably from 1000 to 2800, even more preferably from 1100 to 2600, and particularly preferably from 1500 to 2500. When the number average molecular weight is 1000 or greater, the surface hardness of the hard coat layer tends to further improve. The heat resistance and abrasion resistance of the hard coat layer also tend to improve. On the other hand, when the number average molecular weight is 3000 or less, the compatibility with other components in the curable composition tends to improve and the heat resistance of the hard coat layer tends to improve.

The molecular weight dispersity (Mw/Mn) of the silsesquioxane (X) determined by gel permeation chromatography calibrated with polystyrene is not particularly limited, but is preferably from 1.0 to 3.0, more preferably from 1.1 to 2.0, even more preferably from 1.2 to 1.9, yet even more preferably from 1.3 to 1.8, and particularly preferably from 1.45 to 1.80. When the molecular weight dispersity is 3.0 or less, the surface hardness of the hard coat layer tends to further increase. On the other hand, when the molecular weight dispersity is 1.0 or greater (in particular, 1.1 or greater), the silsesquioxane (X) tends to easily become a liquid, and handling ease tends to improve.

The number average molecular weight and the molecular weight dispersity of the silsesquioxane (X) can be measured with the following instrument and conditions.
Measuring instrument: “LC-20AD” (trade name, available from Shimadzu Corporation)
Column: Shodex KF-801 x quantity of 2, KF-802, and KF-803 (available from Showa Denko K.K.)
Measurement temperature: 40° C.
Eluent: THF, sample concentration of from 0.1 to 0.2 mass %
Flow rate: 1 mL/min
Detector: UV-VIS detector (“SPD-20A” (trade name) available from Shimadzu Corporation)
Molecular weight: calibrated with standard polystyrene

The method for producing the polyorganosilsesquioxane is not particularly limited, and the polyorganosilsesquioxane can be produced by a well-known or commonly used silsesquioxane production method. Examples include a method of subjecting one or more types of hydrolyzable silane compounds to hydrolysis and condensation.

The content proportion of the polyorganosilsesquioxane in the curable composition is not particularly limited, but relative to the total amount (100 mass %) of the curable compounds, the content of the polyorganosilsesquioxane therein is preferably greater than 50 mass % (for example, greater than 50 mass % and less than or equal to 98 mass %), more preferably from 60 to 96 mass %, even more preferably from 70 to 95 mass %, and particularly preferably from 80 to 93 mass %. When the content proportion thereof is greater than 50 mass %, the surface hardness of the hard coat layer tends to further improve. When the above content proportion is 98 mass % or less, other components can be blended, and the effects provided by blending these components tend to further improve. Moreover, a curing catalyst can be blended, and thereby curing of the curable composition tends to proceed more efficiently.

The curable composition may contain a compound (hereinafter, also referred to as a “compound A”) having one or more cationically polymerizable groups and one or more radically polymerizable groups per molecule. When the curable composition contains the compound A, the crosslinking density when the curable composition is formed into a cured product can be effectively increased, a high surface hardness and excellent bendability and bending durability are more easily imparted to the hard coat layer, and antifouling performance is less likely to be reduced. Note that a single type of the compound A may be used alone, or two or more types may be used in combination.

Examples of the “cationically polymerizable group” of the compound A include an epoxy group, an oxetanyl group, and a vinyl ether group, and an epoxy group is preferable from the viewpoint of suppressing a decrease in surface hardness, bendability, and bending durability of the hard coat layer. Note that when the compound A has two or more cationically polymerizable groups, these cationically polymerizable groups may each be the same or different.

Examples of the “radically polymerizable group” of the compound A include a (meth)acryloyl group and a vinyl group, and from the viewpoint of the surface hardness and bending durability of the hard coat layer, a (meth)acryloyl group is preferable. Note that when the compound A has two or more radically polymerizable groups, these radically polymerizable groups may each be the same or different.

The number of the cationically polymerizable groups per molecule of the compound A is not particularly limited as long as the number thereof is 1 or greater, but is preferably from 1 to 5, more preferably from 1 to 3, and even more preferably 1 or 2. In addition, the number of the radically polymerizable groups per molecule of the compound A is not particularly limited as long as the number thereof is 1 or greater, but for example, the number thereof is preferably from 1 to 5, more preferably from 1 to 3, and even more preferably 1 or 2.

The functional group equivalent of the cationically polymerizable group of the compound A is not particularly limited, but is preferably from 50 to 500, more preferably from 80 to 480, and even more preferably from 120 to 450. When the above functional group equivalent is 50 or greater, sufficient bending durability of the hard coat layer can be easily achieved. When the above functional group equivalent is 500 or less, sufficient surface hardness of the hard coat layer can be achieved. Note that the functional group equivalent of the cationically polymerizable group of the compound A can be calculated from the following equation. [Functional group equivalent of cationically polymerizable group]=[molecular weight of compound A]/[number of cationically polymerizable groups in compound A]

The functional group equivalent of the radically polymerizable group of the compound A is not particularly limited, but is preferably from 50 to 500, more preferably from 80 to 480, and even more preferably from 120 to 450. When the above functional group equivalent is 50 or greater, sufficient bending durability of the hard coat layer can be easily achieved. When the above functional group equivalent is 500 or less, sufficient surface hardness of the hard coat layer can be achieved. Note that the functional group equivalent of the radically polymerizable group of the compound A can be calculated from the following equation. [Functional group equivalent of radically polymerizable group]=[molecular weight of compound A]/[number of radically polymerizable groups in compound A]

Specific examples of the compound A include compounds having an epoxy group and a (meth)acryloyl group per molecule, such as 3,4-epoxycyclohexylmethyl (meth)acrylate, glycidyl (meth)acrylate, tripropylene glycol diglycidyl ether di(meth)acrylate (a compound produced by reacting (meth)acrylic acid with both epoxy groups of tripropylene glycol diglycidyl ether), tripropylene glycol diglycidyl ether half (meth)acrylate (a compound produced by reacting (meth)acrylic acid with one epoxy group of tripropylene glycol diglycidyl ether), bisphenol A epoxy (meth)acrylate (a compound produced by reacting (meth)acrylic acid with both epoxy groups of bisphenol A diglycidyl ether), bisphenol A epoxy half (meth)acrylate (a compound produced by reacting (meth)acrylic acid or a derivative thereof with one epoxy group of bisphenol A diglycidyl ether), bisphenol F epoxy di(meth)acrylate, bisphenol F epoxy half (meth)acrylate, bisphenol S epoxy di(meth)acrylate, and bisphenol S epoxy half (meth)acrylate; compounds having an oxetanyl group and a (meth)acryloyl group per molecule, such as 3-oxetanyl methyl(meth)acrylate, 3-methyl-3-oxetanyl methyl(meth)acrylate, 3-ethyl-3-oxetanyl methyl (meth)acrylate, 3-butyl-3-oxetanyl methyl (meth)acrylate, and 3-hexyl-3-oxetanyl methyl (meth)acrylate; and compounds having a vinyl ether group and a (meth)acryloyl group per molecule, such as 2-vinyloxy ethyl (meth)acrylate, 3-vinyloxy propyl (meth)acrylate, 1-methyl-2-vinyloxy ethyl (meth)acrylate, 2-vinyloxy propyl (meth)acrylate, 4-vinyloxy butyl (meth)acrylate, 1-methyl-3-vinyloxy propyl (meth)acrylate, 1-vinyloxy methylpropyl (meth)acrylate, 2-methyl-3-vinyloxy propyl (meth)acrylate, 1,1-dimethyl-2-vinyloxy ethyl (meth)acrylate, 3-vinyloxy butyl (meth)acrylate, 1-methyl-2-vinyloxy propyl (meth)acrylate, 2-vinyloxy butyl (meth)acrylate, 4-vinyloxy cyclohexyl (meth)acrylate, 6-vinyloxy hexyl (meth)acrylate, 4-vinyloxy methylcyclohexyl methyl (meth)acrylate, 3-vinyloxy methylcyclohexyl methyl (meth)acrylate, 2-vinyloxy cyclohexyl methyl (meth)acrylate, p-vinyloxy methylphenyl methyl (meth)acrylate, m-vinyloxy methylphenyl methyl (meth)acrylate, o-vinyloxy methylphenyl methyl (meth)acrylate, 2-(vinyloxyethoxy)ethyl (meth)acrylate, 2-(vinyloxyisopropoxy)ethyl (meth)acrylate, 2-(vinyloxyethoxy)propyl (meth)acrylate, 2-(vinyloxyethoxy)isopropyl (meth)acrylate, 2-(vinyloxyisopropoxy)propyl (meth)acrylate, 2-(vinyloxyisopropoxy)isopropyl (meth)acrylate, 2-(vinyloxyethoxyethoxy)ethyl (meth)acrylate, 2-(vinyloxyethoxyisopropoxy)ethyl (meth)acrylate, 2-(vinyloxyisopropoxyethoxy)ethyl (meth)acrylate, 2-(vinyloxyisopropoxyisopropoxy)ethyl (meth)acrylate, 2-(vinyloxyethoxyethoxy)propyl (meth)acrylate, 2-(vinyloxyethoxyisopropoxy)propyl (meth)acrylate, 2-(vinyloxyisopropoxyethoxy)propyl (meth)acrylate, 2-(vinyloxyisopropoxyisopropoxy)propyl (meth)acrylate, 2-(vinyloxyethoxyethoxy)isopropyl (meth)acrylate, 2-(vinyloxyethoxyisopropoxy)isopropyl (meth)acrylate, 2-(vinyloxyisopropoxyethoxy)isopropyl (meth)acrylate, 2-(vinyloxyisopropoxyisopropoxy)isopropyl (meth)acrylate, 2-(vinyloxyethoxyethoxyethoxy)ethyl (meth)acrylate, 2-(vinyloxyethoxyethoxyethoxyethoxy)ethyl (meth)acrylate, 2-(isopropenoxyethoxy)ethyl (meth)acrylate, 2-(isopropenoxyethoxyethoxy)ethyl (meth)acrylate, 2-(isopropenoxyethoxyethoxyethoxy)ethyl (meth)acrylate, 2-(isopropenoxyethoxyethoxyethoxyethoxy)ethyl (meth)acrylate, polyethylene glycol monovinyl ether (meth)acrylate, and polypropylene glycol monovinyl ether (meth)acrylate.

From the perspective of the bending durability and surface hardness of the hard coat layer, the compound A is preferably a compound having, per molecule, an epoxy group as a cationically polymerizable group and a (meth)acryloyl group as a radically polymerizable group, and specifically, 3,4-epoxycyclohexylmethyl (meth)acrylate, glycidyl (meth)acrylate, tripropylene glycol diglycidyl ether half (meth)acrylate, bisphenol A epoxy half (meth)acrylate, bisphenol F epoxy half (meth)acrylate, and bisphenol S epoxy half (meth)acrylate are preferable.

The compound A can be produced by a known method, for example, by a method of reacting some of cationically polymerizable groups of a compound having two or more cationically polymerizable groups (for example, epoxy groups) per molecule with a carboxylic acid (for example, acrylic acid or methacrylic acid) having a radically polymerizable group, or with a derivative thereof. Furthermore, commercially available products such as products of the trade names “Light Ester G”, “Epoxy Ester 200PA”, and “Epoxy Ester 200PA-E5” (the above are available from Kyoeisha Chemical Co., Ltd.), and a product of the trade name “NK OLIGO EA1010N” (available from Shin-Nakamura Chemical Co., Ltd.) may also be used as the compound A.

The content proportion of the compound A in the curable composition is not particularly limited, but in relation to the total amount (100 mass %) of the curable compound, the content of the compound A is preferably from 0.05 to 8 mass %, more preferably from 0.1 to 5 mass %, and even more preferably from 0.2 to 3 mass %. When the content proportion of the compound A is within the above range, the sebum adhesion resistance of the hard coat layer is more excellent.

The content (blended amount) of the compound A in the curable composition is not particularly limited, but as a solid content relative to 100 parts by mass of the polyorganosilsesquioxane, the content of the compound A is preferably from 1 to 100 parts by mass, more preferably from 1.5 to 75 parts by mass, and even more preferably from 2 to 50 parts by mass. When the content of the compound A is 1 part by mass or greater, the bendability and bending durability of the hard coat layer tend to further improve. On the other hand, when the content of the compound A is 100 parts by mass or less, the surface hardness of the hard coat layer tends to be maintained.

In addition, the curable composition preferably contains an aliphatic compound (hereinafter, may be referred to as a compound B) having two or more cationically polymerizable groups per molecule, and more preferably contains two or more types of the compound B. By blending the compound B, the curable composition can impart flexibility to the hard coat layer, and bending and bending durability can be easily exhibited. In particular, when the curable composition contains two or more types of the compounds B, higher bendability can be exhibited while the surface hardness is maintained. The compound B is a compound that does not correspond to the polyorganosilsesquioxane or the compound A.

Examples of the cationically polymerizable group include the same groups as those exemplified for the compound A. Examples thereof include an epoxy group, an oxetanyl group, and a vinyl ether group, and from the viewpoint of exhibiting surface hardness, bendability, and bending durability of the hard coat layer, an epoxy group is preferable, whereas from the viewpoint of reactivity, a glycidyl group is more preferable. Note that the two or more cationically polymerizable groups of the compound B may be the same or different.

The number of the cationically polymerizable groups per molecule of the compound B is not particularly limited as long as the number thereof is 2 or greater, but for example, the number thereof is preferably from 2 to 5, more preferably 2 or 3, and even more preferably 2.

The “aliphatic compound” in the compound B is an aliphatic compound having no cyclic structure other than the cationically polymerizable group. Examples of the compound B include glycidyl ethers of dihydric or higher alcohols having no cyclic structure; and glycidyl esters of divalent or higher carboxylic acids [such as, for example, adipic acid, sebacic acid, maleic acid, and itaconic acid]. Here, examples of the dihydric or higher alcohol having no cyclic structure include dihydric alcohols, such as ethylene glycol, 1,2-propanediol, 1,3-propanediol, 1,4-butanediol, neopentyl glycol, 1,6-hexanediol, diethylene glycol, triethylene glycol, tetraethylene glycol, dipropylene glycol, polyethylene glycol, and polypropylene glycol; and trihydric or higher polyhydric alcohols, such as glycerin, diglycerin, erythritol, trimethylolethane, trimethylolpropane, pentaerythritol, dipentaerythritol, and sorbitol. In addition, the dihydric or higher alcohol may be a polyether polyol, a polyester polyol, a polycarbonate polyol, a polyolefin polyol, or the like.

As the compound B, a compound having two cationically polymerizable functional groups at both terminals of the aliphatic compound is preferable, and specifically, a compound represented by the following Formula (A) is preferable.

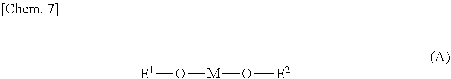

In Formula (A), M represents a linear or branched alkylene group having from 2 to 10 carbons or an ethylene glycol group having from 5 to 15 repeating units. Examples of the linear or branched alkylene group having from 2 to 10 carbons include an ethylene group, a propylene group, a trimethylene group, a tetramethylene group, a pentamethylene group, a hexamethylene group, and a decamethylene group. Among these, from the viewpoint of improving the surface hardness, bendability, and bending durability of the hardcoatless layer and inhibiting a decrease in the antifouling performance, M is preferably a linear or branched alkylene group having from 3 to 8 carbon atoms, more preferably a linear alkylene group having from 5 to 7 carbon atoms, and still more preferably a linear alkylene group having 6 carbon atoms (a hexamethylene group). Examples of the ethylene glycol group having from 5 to 15 repeating units include a hexaethylene glycol group, a nonaethylene glycol group, and a decaethylene glycol group, but in order to further improve bendability while maintaining surface hardness, the ethylene glycol group thereof is preferably a nonaethylene glycol group. When the curable composition contains two or more types of the compounds B, the curable composition preferably contains a type of the compound B in which M is a linear or branched alkylene group having from 2 to 10 carbons as well as a type of the compound B in which M is an ethylene glycol group having from 5 to 15 repeating units.

In Formula (A), E¹ and E² may be the same or different, each represents a cationically polymerizable functional group, and each is preferably a group represented by the following Formula (E) from the viewpoints of improving reactivity and the surface hardness, bendability, and bending durability of the hard coat layer, and inhibiting a decrease in antifouling performance.

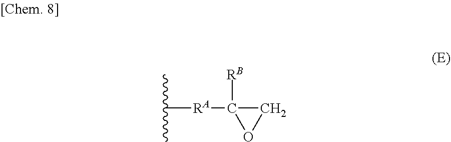

In Formula (E), R^{A} denotes a linear or branched alkylene group having from 1 to 6 carbons. Examples of the linear or branched alkylene group having from 1 to 6 carbons include a methylene group, a methylmethylene group, a dimethylmethylene group, an ethylene group, a propylene group, a trimethylene group, a tetramethylene group, a pentamethylene group, a hexamethylene group, and a decamethylene group. Among these, from the viewpoints of improving reactivity and the surface hardness, bendability, and bending durability of the hard coat layer and inhibiting a decrease in the antifouling performance, R^{A} is preferably a linear alkylene group having from 1 to 4 carbons, more preferably a methylene group or an ethylene group, and even more preferably a methylene group. R^{B} is a hydrogen atom or a linear or branched alkyl group having from 1 to 6 carbons, and is preferably hydrogen atom or a methyl group, and more preferably a hydrogen atom.

The functional group equivalent of the cationically polymerizable group of the compound B is not particularly limited, but is preferably from 50 to 500, more preferably from 80 to 480, and even more preferably from 120 to 450. When the above functional group equivalent is 50 or more, sufficient bending durability of the hard coat layer can be easily achieved. When the above functional group equivalent is 500 or less, sufficient surface hardness of the hard coat layer can be achieved. When the curable composition contains two or more types of the compound B, the epoxy equivalent of at least one type of the compounds B is preferably from 50 to 200, more preferably from 80 to 180, and still more preferably from 100 to 160. In addition, the functional group equivalent of another type of the compounds B is preferably greater than 200 and less than or equal to 500, more preferably from 220 to 450, and still more preferably from 240 to 400. When the curable composition contains a combination of the compounds B having functional group equivalents within the above ranges, higher bendability can be exhibited while the surface hardness is maintained. Note that the functional group equivalent of the cationically polymerizable group of the compound B can be calculated from the following equation.

[Functional group equivalent of cationically polymerizable group]=[molecular weight of compound B]/[number of cationically polymerizable groups in compound B]

Hereinafter, in the present specification, a compound B having a functional group equivalent of from 50 to 200 may be referred to as a “short chain length compound B”, and a compound B having a functional group equivalent of greater than 200 and less than or equal to 500 may be referred to as a “long chain length compound B”.

Specific examples of the compound B include alkylene glycol diglycidyl ethers (alkanediol diglycidyl ethers) such as ethylene glycol diglycidyl ether, 1,3-propanediol diglycidyl ether, 2-methyl-1,3-propanediol diglycidyl ether, 2-butyl-2-ethyl-1,3-propanediol diglycidyl ether, 1,4-butanediol diglycidyl ether (tetramethyleneglycol diglycidyl ether), neopentylglycol diglycidyl ether, 3-methyl-2,4-pentanediol diglycidyl ether, 2,4-pentanediol diglycidyl ether, 1,5-pentanediol diglycidyl ether (pentamethyleneglycol diglycidyl ether), 3-methyl-1,5-pentanediol diglycidyl ether, 2-methyl-2,4-pentanediol diglycidyl ether, 2,4-diethyl-1,5-pentanediol diglycidyl ether, 1,6-hexanediol diglycidyl ether (hexamethyleneglycol diglycidyl ether), 1,7-heptanediol diglycidyl ether, 3,5-heptanediol diglycidyl ether, 1,8-octanediol diglycidyl ether, 2-methyl-1,8-octanediol diglycidyl ether, and 1,9-nonanediol diglycidyl ether; and (poly) alkylene glycol diglycidyl ethers such as diethylene glycol diglycidyl ether, propylene glycol diglycidyl ether, triethylene glycol diglycidyl ether, hexaethylene glycol diglycidyl ether, and nonaethylene glycol diglycidyl ether. Among these, the curable composition preferably includes, as the compound B, a diol diglycidyl ether and a (poly)alkylene glycol diglycidyl ether, more preferably includes a diol diglycidyl ether that is a short chain length compound B and a (poly)alkylene glycol diglycidyl ether that is a long chain length compound B, and particularly preferably includes a combination of nonaethylene glycol diglycidyl ether and 1,6-hexanediol diglycidyl ether.

Examples of commercially available products of the compound B include products of the trade names “Epolight 40E”, “Epolight 100E”, “Epolight 200E”, “Epolight 400E”, “Epolight 1600”, and “Epolight 1600N” (available from Kyoeisha Chemical Co., Ltd.), and a product of the trade name “YH-300” (available from Nippon Steel Chemical & Material Co., Ltd.).

The content proportion of the compound B in the curable composition is not particularly limited, but in relation to the total amount (100 mass %) of the curable compounds, the content of the compound B is preferably from 1 to 20 mass %, more preferably from 3 to 15 mass %, and even more preferably from 5 to 13 mass %. When the content proportion thereof is within the above range, the bendability of the transparent laminate becomes more appropriate.

The content of the compound B is not particularly limited, but as a solid content in relation to 100 parts by mass of the polyorganosilsesquioxane, the content of the compound B is preferably from 1 to 20 parts by mass, more preferably from 3 to 17 parts by mass, and even more preferably from 5 to 15 parts by mass. When the content thereof is within the above range, the bendability of the transparent laminate becomes more appropriate.

In addition, in a case in which the curable composition contains a short chain length compound B as well as a long chain length compound B, the content of the long chain length compound B is preferably from 35 to 95 mass %, more preferably from 50 to 90 mass %, and still more preferably from 65 to 87 mass % per the total amount (100 mass %) of the compounds B. When the content of the long chain length compound B among the compounds B is 35 mass % or greater, bendability can be easily exhibited. Moreover, when the content thereof is 95 mass % or less, the surface hardness can be sufficiently increased.

The curable composition preferably contains a curing catalyst. The curing catalyst is a compound that can initiate and promote polymerization reactions of the curable compounds such as the polyorganosilsesquioxane, the compound A, and the compound B. A single type of the above curing catalyst may be used alone, or two or more types may be used in combination.

The curing catalyst is selected according to the types of the curable functional groups of the curable compounds, and among the different types of curing catalysts, a cationic polymerization initiator and/or a radical polymerization initiator is preferable. The cationic polymerization initiator is a compound that generates a cationic species in response to heat or irradiation with active energy rays, and thereby initiates a curing reaction of the curable compounds.

Examples of the cationic polymerization initiator include a photocationic polymerization initiator (a photo acid generating agent) and a thermal cationic polymerization initiator (a thermal acid generating agent).

Known or commonly used photocationic polymerization initiators can be used as the photocationic polymerization initiator, and examples thereof include a sulfonium salt (a salt of a sulfonium ion and an anion), an iodonium salt (a salt of an iodonium ion and an anion), a selenium salt (a salt of a selenium ion and an anion), an ammonium salt (a salt of an ammonium ion and an anion), a phosphonium salt (a salt of a phosphonium ion and an anion), and a salt of a transition metal complex ion and an anion.

Examples of the sulfonium salt include a triarylsulfonium salt, such as a triphenylsulfonium salt, a tri-p-tolylsulfonium salt, a tri-o-tolylsulfonium salt, a tris(4-methoxyphenyl)sulfonium salt, a 1-naphthyldiphenylsulfonium salt, a 2-naphthyldiphenylsulfonium salt, a tris(4-fluorophenyl)sulfonium salt, a tri-1-naphthylsulfonium salt, a tri-2-naphthylsulfonium salt, a tris(4-hydroxyphenyl)sulfonium salt, a diphenyl[4-(phenylthio)phenyl]sulfonium salt, a 4-(p-tolylthio)phenyldi-(p-phenyl)sulfonium salt; a diarylsulfonium salt, such as a diphenylphenacylsulfonium salt, a diphenyl 4-nitrophenacylsulfonium salt, a diphenylbenzylsulfonium salt, and a diphenylmethylsulfonium salt; a monoarylsulfonium salt, such as a phenylmethylbenzylsulfonium salt, a 4-hydroxyphenylmethylbenzylsulfonium salt, and a 4-methoxyphenylmethylbenzyl sulfonium salt; and a trialkyl sulfonium salt, such as a dimethylphenacyl sulfonium salt, a phenacyl tetrahydrothiophenium salt, and a dimethyl benzylsulfonium salt.

Examples of the diphenyl [4-(phenylthio)phenyl]sulfonium salt include diphenyl[4-(phenylthio)phenyl]sulfonium tetrakis(pentafluorophenyl) borate and diphenyl[4-(phenylthio)phenyl]sulfonium hexafluorophoshate. Furthermore, commercially available products such as “CPI-100P” (trade name, diphenyl[4-(phenylthio)phenyl]sulfonium hexafluorophosphate in 50% propylene carbonate solution, available from San-Apro Ltd.) can also be used.

Examples of the iodonium salt include the “Rhodorsil Photoinitiator 2074” (trade name, tetrakis(pentafluorophenyl)borate [(1-methylethyl)phenyl](methylphenyl)iodonium, available from Rhodia Japan Ltd.), “WPI-124” (trade name, available from Wako Pure Chemical Industries, Ltd.), a diphenyliodonium salt, a di-p-tolyliodonium salt, a bis(4-dodecylphenyl)iodonium salt, and a bis(4-methoxyphenyl)iodonium salt.

Examples of the selenium salt include a triarylselenium salt, such as a triphenylselenium salt, a tri-p-tolylselenium salt, a tri-o-tolylselenium salt, a tris(4-methoxyphenyl)selenium salt, and a 1-naphthyldiphenylselenium salt; a diarylselenium salt, such as a diphenylphenacylselenium salt, a diphenylbenzylselenium salt, and a diphenylmethylselenium salt; a monoarylselenium salt, such as a phenylmethylbenzylselenium salt; and a trialkylselenium salt, such as a dimethylphenacylselenium salt.

Examples of the ammonium salt include a tetraalkyl ammonium salt, such as a tetramethyl ammonium salt, an ethyltrimethyl ammonium salt, a diethyldimethyl ammonium salt, a triethylmethyl ammonium salt, a tetraethyl ammonium salt, a trimethyl-n-propyl ammonium salt, and a trimethyl-n-butyl ammonium salt; a pyrrolidium salt, such as an N,N-dimethylpyrrolidium salt and an N-ethyl-N-methylpyrrolidium salt; an imidazolinium salt, such as an N,N′-dimethylimidazolinium salt and an N,N′-diethylimidazolinium salt; a tetrahydropyrimidium salt, such as an N,N′-dimethyltetrahydropyrimidium salt and an N,N′-diethyltetrahydropyrimidium salt; a morpholinium salt, such as an N,N-dimethylmorpholinium salt and an N,N-diethylmorpholinium salt; a piperidinium salt, such as an N,N-dimethylpiperidinium salt and an N,N-diethylpiperidinium salt; a pyridinium salt, such as an N-methylpyridinium salt and an N-ethylpyridinium salt; an imidazolium salt, such as an N,N′-dimethylimidazolium salt; a quinolium salt, such as an N-methylquinolium salt; an isoquinolium salt, such as an N-methylisoquinolium salt; a thiazonium salt, such as a benzylbenzothiazonium salt; and an acrydium salt, such as a benzylacrydium salt.

Examples of the phosphonium salt include a tetra-arylphosphonium salt, such as a tetra-phenylphosphonium salt, a tetra-p-tolylphosphonium salt, and a tetrakis(2-methoxyphenyl)phosphonium salt; a triarylphosphonium salt, such as a triphenylbenzylphosphonium salt; and a tetra-alkylphosphonium salt, such as a triethylbenzylphosphonium salt, a tributylbenzylphosphonium salt, a tetra-ethylphosphonium salt, a tetra-butylphosphonium salt, and a triethylphenacylphosphonium salt.

Examples of the salt of a transition metal complex ion include a salt of a chromium complex cation, such as (η⁵-cyclopentadienyl)(η⁶-toluene)Cr⁺ and (η⁵-cyclopentadienyl)(η⁶-xylene)Cr⁺; and a salt of an iron complex cation, such as (η⁵-cyclopentadienyl)(η⁶-toluene)Fe⁺ and (η⁵-cyclopentadienyl)(η⁶-xylene)Fe⁺.

Examples of anions constituting the above-described salts include PF₆⁻, BF₄⁻, (C₆F₅)₄B⁻, (C₆F₅)₄Ga⁻, a sulfonate anion (such as trifluoromethane sulfonate anion, pentafluoroethane sulfonate anion, methane sulfonate anion, benzene sulfonate anion, and p-toluene sulfonate anion), a perhalogenate ion, a halogenated sulfonate ion, sulfate ion, carbonate ion, aluminate ion, carboxylate ion, arylborate ion, thiocyanate ion, and nitrate ion.

Examples of the thermal cationic polymerization initiator include an arylsulfonium salt, an aryliodonium salt, an allene-ion complex, a quaternary ammonium salt, an aluminum chelate, and a boron trifluoride amine complex. Examples of anions constituting the above-described salts include the same examples as the anions of the photocationic polymerization initiators described above.

Examples of the arylsulfonium salt include pentafluorophenyl borate and hexafluorophosphate. In the curable composition according to an embodiment of the present disclosure, a commercially available product can be used, such as, for example, products of the trade names “SP-66” and “SP-77” (available from Adeka Corporation); and products of the trade names “SAN-AID SI-150L”, “SAN-AID SI-110”, “SAN-AID SI-360”, “SAN-AID SI-300”, “SAN-AID SI-B4”, “SAN-AID SI-B5”, “SAN-AID SI-B3”, “SAN-AID SI-B3A”, “SAN-AID SI-B7”, and “SAN-AID SI-B2A” (available from Sanshin Chemical Industry Co., Ltd.). Examples of the aluminum chelate include ethylacetoacetate aluminum diisopropylate and aluminum tris(ethylacetoacetate). Moreover, examples of the boron trifluoride amine complex include a boron trifluoride monoethyl amine complex, a boron trifluoride imidazole complex, and a boron trifluoride piperidine complex.

The radical polymerization initiator is a compound that generates radicals in response to heat or irradiation with active energy rays, and thereby initiates a curing reaction of the curable compound.

Examples of the radical polymerization initiator include a photoradical polymerization initiator and a thermal radical polymerization initiator. Examples of the photoradical polymerization initiator include an alkylphenone-based photoradical polymerization initiator, an acylphosphine oxide-based photoradical polymerization initiator, an oxime ester-based photoradical polymerization initiator, and an a-hydroxyketone-based photoradical polymerization initiator.

Examples of the alkylphenone-based photoradical polymerization initiator include oligomers of 2-hydroxy-2-methyl-1-phenylpropan-1-one, 2-benzyl-2-dimethylamino-1-(4-morpholinophenyl)-1-butanone, 2-(dimethylamino)-2-[(4-methylphenyl) methyl]-[4-(4-morpholinyl) phenyl]-1-butanone, 2-methyl-1-[4-(methylthio)phenyl]-2-morpholinopropan-1-one, benzophenone, methylbenzophenone, o-benzoylbenzoic acid, benzoylethyl ether, 2,2-diethoxyacetophenone, 2,4-diethylthioxanthone, diphenyl-(2,4,6-trimethylbenzoyl) phosphineoxide, ethyl-(2,4,6-trimethylbenzoyl) phenylphosphinate, 4,4′-bis(diethylamino)benzophenone, 1-hydroxycyclohexylphenyl ketone, 2,2-dimethoxy-1,2-diphenylethan-1-one, 1-[4-(2-hydroxyethoxy)phenyl]-2-hydroxy-2-methyl-1-propan-1-one, and 2-hydroxy-1-(4-isopropenylphenyl)-2-methylpropan-1-one.

Examples of the acylphosphine oxide-based photoradical polymerization initiators include 2,4,6-trimethylbenzoyl diphenylphosphine oxide and bis(2,4,6-trimethylbenzoyl) phenylphosphine oxide.

Examples of the oxime ester-based photoradical polymerization initiator include 1-[4-(phenylthio)phenyl]-1,2-octandione 2-(O-benzoyloxime) and 1-[6-(2-methylbenzoyl)-9-ethyl-9H-carbazol-3-yl]ethanone O-acetyloxime.

Examples of the a-hydroxyketone-based photoradical polymerization initiator include benzoin, benzoin methyl ether, benzoin butyl ether, 1-hydroxycyclohexylphenyl ketone, 1-phenyl-2-hydroxy-2-methylpropan-1-one, 1-(4-i-propylphenyl)-2-hydroxy-2-methylpropan-1-one, 4-(2-hydroxyethoxy) phenyl-(2-hydroxy-2-propyl) ketone, and 1-hydroxycyclohexylphenyl ketone.

The content (blending amount) of the curing catalyst in the curable composition is not particularly limited, but is preferably from 0.01 to 10 parts by mass, more preferably from 0.03 to 5 parts by mass, and still more preferably from 0.05 to 3 parts by mass, per 100 parts by mass of the total amount of the curable compounds. When the content of the curing catalyst is 0.01 parts by mass or greater, the curing reaction can be efficiently and sufficiently advanced, and the surface hardness of the hard coat layer tends to further improve. On the other hand, when the content of the curing catalyst is 10 parts by mass or less, the storage properties of the curable composition tend to improve, and coloration of the cured product tends to be inhibited.

The content (blending amount) of the cationic polymerization initiator in the curable composition is not particularly limited, but is preferably from 0.05 to 10 parts by mass, more preferably from 0.1 to 5 parts by mass, still more preferably from 0.15 to 3 parts by mass, and particularly preferably from 0.2 to 2 parts by mass, per 100 parts by mass of the total amount of the curable compounds. When the content thereof is 0.05 parts by mass or greater, the curing reaction can be efficiently and sufficiently advanced, and the surface hardness of the resulting cured product tends to further improve. On the other hand, when the content thereof is 10 parts by mass or less, the storage properties of the curable composition tend to improve, and coloration of the cured product tends to be inhibited.

The content (blending amount) of the radical polymerization initiator in the curable composition is not particularly limited, but is preferably from 0.1 to 5 parts by mass, more preferably from 0.3 to 3 parts by mass, and still more preferably from 0.5 to 2 parts by mass, per 100 parts by mass of the total amount of the curable compounds. When the content thereof is 0.1 parts by mass or greater, the curing reaction can be efficiently and sufficiently advanced, and the surface hardness of the resulting cured product tends to further improve. On the other hand, when the content thereof is 5 parts by mass or less, the storage properties of the curable composition tend to improve, and coloration of the cured product tends to be inhibited.

The curable composition preferably contains a radically curable polyorganosiloxane as a leveling agent. When the radically curable polyorganosiloxane is used, the smoothness of the surface of the hard coat layer is improved, excellent sebum adhesion resistance is imparted, and the adhesion of fingerprints to the surface of the hard coat layer is inhibited. In addition, the above active energy ray curable polyorganosiloxane preferably does not correspond to a compound corresponding to a PFAS, and in this case, the above-described effects are exhibited even though the radically curable polyorganosiloxane does not correspond to a compound corresponding to a PFAS. The radically curable polyorganosiloxane is radically curable, and therefore also corresponds to the abovementioned curable compound. A single type of the radically curable polyorganosiloxane may be used alone, or two or more types may be used in combination.

The radically curable polyorganosiloxane has a radically polymerizable functional group in the molecule. Examples of the radically curable functional group include a photoradically polymerizable functional group.

Examples of the photoradically polymerizable functional group include a (meth)acryloyl group, a (meth)acrylamide group, a vinyl group, and a vinylthio group. Among these, a (meth)acryloyl group is preferred.

The polyorganosiloxane in the radically curable polyorganosiloxane is preferably a linear polyorganosiloxane from the viewpoint of exhibiting a greater effect as a leveling agent.

The content of the radically curable polyorganosiloxane is not particularly limited, but as a solid content in relation to 100 parts by mass of the polyorganosilsesquioxane, the content of the radically curable polyorganosiloxane is preferably from 0.01 to 5 parts by mass, more preferably from 0.05 to 3 parts by mass, and even more preferably from 0.1 to 2 parts by mass.

The curable composition preferably contains an antioxidant. When the curable composition contains an antioxidant, the storage properties of the hard coat layer tend to further improve. A single type of antioxidant may be used alone, or two or more types may be used in combination.

As the antioxidant, a well-known or commonly used antioxidant can be used, and examples thereof include, but are not particularly limited to, a phenol-based antioxidant, a hindered amine-based antioxidant, a phosphorus-based antioxidant, and a sulfur-based antioxidant.

Examples of the phenol-based antioxidant include monophenols such as 2,6-di-t-butyl-p-cresol, butylated hydroxyanisole, 2,6-di-t-butyl-p-ethylphenol, and stearyl-β-(3,5-di-t-butyl-4-hydroxyphenyl) propionate; bisphenols such as 2,2′-methylenebis(4-methyl-6-t-butylphenol), 2,2′-methylenebis(4-ethyl-6-t-butylphenol), 4,4′-thiobis(3-methyl-6-t-butylphenol), 4,4′-butylidenebis(3-methyl-6-t-butylphenol), and 3,9-bis[1,1-dimethyl-2-{β-(3-t-butyl-4-hydroxy-5-methylphenyl)propionyloxy}ethyl]2,4,8,10-tetraoxaspiro[5.5]undecane; and polymeric phenols such as 1,1,3-tris(2-methyl-4-hydroxy-5-t-butylphenyl)butane, 1,3,5-trimethyl-2,4,6-tris(3,5-di-t-butyl-4-hydroxybenzyl)benzene, tetrakis-[methylene-3-(3′,5′-di-t-butyl-4′-hydroxyphenyl)propionate]methane, bis[3,3′-bis(4′-hydroxy-3′-t-butylphenyl)butyric acid]glycol ester, 1,3,5-tris(3′,5′-di-t-butyl-4′-hydroxybenzyl)-s-triazine-2,4,6-(1H,3H,5H)trione, and tocophenol.

Examples of the hindered amine-based antioxidant include bis(1,2,2,6,6-pentamethyl-4-piperidyl)[[3,5-bis (1,1-dimethyl ethyl)-4-hydroxyphenyl]methyl]butyl malonate, bis(1,2,2,6,6-pentamethyl-4-piperidyl) sebacate, methyl-1,2,2,6,6-pentamethyl-4-piperidyl sebacate, and 4-benzoyloxy-2,2,6,6-tetramethylpiperidine.

Examples of the phosphorus-based antioxidant include phosphites such as triphenyl phosphite, diphenylisodecyl phosphite, phenyldiisodecyl phosphite, tris(nonylphenyl)phosphite, diisodecyl pentaerythritol phosphite, tris(2,4-di-t-butylphenyl) phosphite, cyclic neopentanetetraylbis(octadecyl)phosphite, cyclic neopentanetetraylbis(2,4-di-t-butylphenyl)phosphite, cyclic neopentanetetraylbis(2,4-di-t-butyl-4-methylphenyl)phosphite, and bis[2-t-butyl-6-methyl-4-{2-(octadecyloxycarbonyl)ethyl}phenyl]hydrogen phosphite; and oxaphosphaphenanthrene oxides such as 9,10-dihydro-9-oxa-10-phosphaphenanthrene-10-oxide, and 10-(3,5-di-t-butyl-4-hydroxybenzyl)-9,10-dihydro-9-oxa-10-phosphaphenanthrene-10-oxide.

Examples of the sulfur-based antioxidant include dodecanethiol, dilauryl-3,3′-thiodipropionate, dimyristyl-3,3′-thiodipropionate, and distearyl-3,3′-thiodipropionate.

In a case in which the curable composition contains an antioxidant, the content of the antioxidant is not particularly limited, but is preferably from 0.05 to 5 parts by mass and more preferably from 0.1 to 1 parts by mass per the total amount (100 parts by mass) of the curable compounds. When the content of the antioxidant is 0.05 parts by mass or greater, sufficient stability can be provided. In addition, when the content of the antioxidant is 5 parts by mass or less, coloration of the hard coat layer can be suppressed.

When the curable composition contains an antioxidant, the content thereof is not particularly limited, but is preferably from 0.05 to 5 parts by mass and more preferably from 0.1 to 3 parts by mass per 100 parts by mass of the polyorganosilsesquioxane. When the content of the antioxidant is 0.05 parts by mass or greater, sufficient stability can be provided. In addition, when the content of the antioxidant is 5 parts by mass or less, coloration of the hard coat layer can be suppressed.

The curable composition may further contain a solvent. The solvent is not particularly limited as long as the solvent is capable of dissolving the polyorganosilsesquioxane described above and any additives used as necessary, and does not inhibit polymerization. A single type of solvent may be used alone, or two or more types may be used in combination.

The solvent that is used is preferably one that can impart fluidity suitable for coating onto the hard coat layer and that can be easily removed by heating at a temperature at which the progression of polymerization can be suppressed, and preferably, a solvent having a boiling point (at 1 atm) of not higher than 170° C. is used (for example, an aromatic solvent such as toluene, xylene, and mesitylene; an ester such as butyl acetate; a ketone such as methyl isobutyl ketone and cyclohexanone; and an ether such as propylene glycol monomethyl ether and propylene glycol monomethyl ether acetate).

From the viewpoint of excelling in coatability, the solvent is preferably used in a range such that the concentration of nonvolatile content in the curable composition is, for example, preferably from 5 to 100 mass %, more preferably from 10 to 80 mass %, and particularly preferably from 20 to 70 mass %. However, the addition amount is not limited to the range described above, and an optimal addition amount should be selected to adjust to a viscosity at which an appropriate film thickness can be achieved. That is, when the usage amount of the solvent is in excess, the viscosity of the curable composition becomes low, and forming a coating film with an appropriate film thickness tends to be difficult. On the other hand, when the usage amount of the solvent is too low, the viscosity of the curable composition becomes too high, and it tends to be difficult to uniformly apply the curable composition onto the substrate.

The curable composition may further contain, as other components, commonly used additives, such as an inorganic filler, such as precipitated silica, wet silica, fumed silica, calcined silica, titanium oxide, alumina, glass, quartz, aluminosilicic acid, iron oxide, zinc oxide, calcium carbonate, carbon black, silicon carbide, silicon nitride, and boron nitride; an inorganic filler produced by treating the above filler with an organosilicon compound, such as an organohalosilane, organoalkoxysilane, and organosilazane; an organic resin fine powder, such as a silicone resin, an epoxy resin, and a fluororesin; a filler, such as a conductive metal powder of silver, copper, or the like, a curing auxiliary, a stabilizer (such as a light-resistant stabilizer, a heat stabilizer, and a heavy metal inactivator), an ultraviolet absorber (a triazine-based UV absorbers, a benzotriazole-based UV absorber, a benzophenone-based UV absorber, an oxybenzophenone-based UV absorber, a salicylate-based UV absorber, and a cyanoacrylate-based UV absorber), a flame retardant (such as a phosphorus-based flame retardant, a halogen-based flame retardant, and an inorganic flame retardant), a flame retardant auxiliary, a reinforcing material (such as an additional filler), a nucleating agent, a coupling agent (such as a silane coupling agent), a lubricant, a wax, a plasticizer, a releasing agent, an impact modifier, a hue modifier, a transparentizing agent, a rheology modifier (such as a fluidity modifier), a processability modifier, a colorant (such as a dye and a pigment), an antistatic agent, a dispersant, a surface modifier (such as a slipping agent), a matting agent, an antifoaming agent, a foam inhibitor, a deforming agent, an antibacterial agent, a preservative, a viscosity modifier, a thickening agent, a photosensitizer, and a foaming agent. A single type of the other components may be used alone, or two or more types may be used in combination. The content of the other components described above is not particularly limited, but is preferably from 100 parts by mass or less, more preferably from 30 parts by mass or less (for example, from 0.01 to 30 parts by mass), and still more preferably 10 parts by mass or less (for example, from 0.1 to 10 parts by mass), per 100 parts by mass of the total amount of the curable compounds.

Moreover, the curable composition preferably does not contain a compound corresponding to a PFAS. Such configuration enables the curable composition not to use a PFAS, and the curable composition can comply with PFAS regulations.

The above-described curable composition can be prepared by agitating and mixing components described above at room temperature or under heating as necessary, but the preparation method is not limited thereto. Here, the curable composition can be used as a one-part composition that contains components mixed in advance and is used as is, or alternatively, the curable composition can be used as a multi-part (for example, two-part) composition, two or more components of which are separately stored and then mixed at predetermined proportions before use.

The form of the curable composition is not particularly limited but is preferably a liquid at normal temperature (about 25° C.). More specifically, a liquid of the curable composition diluted with a solvent to 20% [in particular, a curable composition solution in which the proportion of methyl isobutyl ketone is 20 mass %] has a viscosity at 25° C. of preferably from 300 to 20000 mPa·s, more preferably from 500 to 10000 mPa·s, and even more preferably from 1000 to 8000 mPa·s. When the viscosity of the curable composition is 300 mPa·s or greater, the cured product (coating film) tends to further improve. On the other hand, when the viscosity thereof is 20000 mPa·s or less, the preparation and handling of the curable composition tend to be facilitated, and air bubbles tend to be less likely to remain in the cured product (coating film). Here, the viscosity of the curable composition is measured using a viscometer (trade name “MCR301”, available from Anton Paar GmbH) under conditions including a swing angle of 5%, a frequency of from 0.1 to 100 (l/s), and a temperature of 25° C.

The method for producing the hard coat layer is not particularly limited, and the hard coat layer can be produced in accordance with a known or commonly used method for producing a hard coat layer. For example, the hard coat layer can be produced by coating at least one surface of the substrate (the undercoat layer surface in a case in which an undercoat layer is formed) with the curable composition, and then if necessary, removing the solvent through drying, followed by curing the curable composition (curable composition layer). The curable composition application method and curing conditions are not particularly limited, and for example, can be appropriately selected from the below-described conditions.

As a method of applying and curing the hard coat layer, an ordinary coating method can be used. Specifically, the same method as the above-described method of applying the undercoat layer may be used. Also note that when the hard coat layer is cured by irradiation with ultraviolet rays, for example, the cumulative irradiation amount is preferably from approximately 1 mJ/cm² to approximately 5000 mJ/cm².

The specific curing conditions are not particularly limited, but for example, the curable composition is first subjected to a heat treatment (pre-baking) at a temperature of preferably 60° C. or higher, more preferably 120° C. or higher, and even more preferably 150° C. or higher for preferably 10 seconds or longer, more preferably 30 seconds or longer, and even more preferably 60 seconds or longer, and is then irradiated with ultraviolet rays (radiation conditions (radiation dose): preferably 300 mJ/cm² or greater; radiation intensity: 100 mW/cm² or greater), and finally, is cured through heat treatment (aging) at a temperature of preferably 120° C. or higher for preferably 0.5 hours or longer. However, the curing conditions are not limited to this range, and the pre-baking temperature and time, and the aging temperature and time can be selected, as appropriate, according to the solvent that is used, and the ultraviolet radiation conditions can be selected, as appropriate, according to the curing agent that is used.

As described above, through application and curing, the curable composition can form a hard coat layer having a high surface hardness and toughness. The transparent laminate including the hard coat layer produced as described above exhibits an improved surface hardness of the hard coat layer while maintaining excellent bendability and bending durability.

In order to further improve the ability to re-coat the hard coat layer, the surface of the hard coat layer may be subjected to a surface treatment such as a corona discharge treatment for modifying the surface through irradiation with a corona discharge, a plasma discharge treatment, an ozone exposure treatment, or an excimer treatment. Among these treatments, the corona discharge treatment is more preferable from the viewpoint of being able to easily improve the ability to re-coat the hard coat layer.

The corona discharge treatment is a process in which the hard coat layer surface is treated by generating a non-uniform electric field around a pointed electrode (needle electrode) and generating a sustained discharge. The plasma discharge treatment is a process in which the hard coat layer surface is treated by generating positively and negatively charged particles activated through discharging in the atmosphere. The ozone exposure treatment is a process in which the hard coat layer surface is treated by generating ozone through ultraviolet irradiation using, for example, a low-pressure mercury lamp in the presence of oxygen. The excimer treatment is a process in which the hard coat layer surface is treated by ultraviolet irradiation or laser irradiation using an excimer lamp in a vacuum state.

The haze of the hard coat layer is preferably 1% or less, more preferably 0.7% or less, and even more preferably 0.5% or less. In addition, the lower limit of the haze is, for example, 0.1%. When the haze is 1% or less, the transparent laminate tends to be suitable for use in applications requiring a high transparency.

The thickness of the hard coat layer is preferably from 5 to 100 μm, and more preferably from 10 to 70 μm. When the thickness of the hard coat layer is 5 μm or greater, sufficient surface hardness can be exhibited. In addition, when the thickness is 100 μm or less, bendability is easily exhibited. When the hard coat layer is formed on both surfaces of the substrate, the thickness of at least one of the hard coat layers is preferably 5 μm or greater, and more preferably 10 μm or greater. Moreover, from the viewpoint of exhibiting bendability, the thickness of each of both hard coat layers is preferably 50 μm or less, and more preferably 45 μm or less.

### Image Display Device

One embodiment of the present disclosure is an image display device provided with the above-described transparent laminate. In the image display device, the transparent laminate is disposed, for example, with the hard coat layer configuring the surface of the viewing side. The image display device is not particularly limited, and examples thereof include display devices such as an organic electroluminescent display device, an inorganic electroluminescent display device, and a liquid crystal display device. In the display device, since the surface of the hard coat layer has sufficient surface hardness, scratches are less likely to occur on the surface, and the touch property is excellent. In addition, since the image display device has excellent bendability and bending durability, the image display device can also be used as a flexible display that can be rolled or the like. Furthermore, since sufficient surface hardness, bendability, and bending durability are exhibited, the image display device can be suitably used as a flexible device that includes the image display device.

Each aspect disclosed in the present specification can be combined with any other feature disclosed herein. Moreover, each of the configurations, combinations thereof, and the like in each of the embodiments are merely examples, and various additions, omissions, and other changes of the configurations may be made, as appropriate, without departing from the spirit of the present disclosure. The present disclosure is not limited by the embodiments and is limited only by the claims.

### EXAMPLES

An embodiment of the present disclosure will be described in detail below based on Examples.

### Production Example 1

### Polyorganosilsesquioxane Production

A 1000 mL flask (reaction vessel) equipped with a thermometer, a stirrer, a reflux condenser, and a nitrogen inlet tube was charged with 277.2 mmol (68.30 g) of 2-(3,4-epoxycyclohexyl)ethyltrimethoxysilane, 3.0 mmol (0.56 g) of phenyltrimethoxysilane, and 275.4 g of acetone under a nitrogen stream, and the temperature was raised to 50° C. To the mixture thus prepared, 7.74 g of a 5% potassium carbonate aqueous solution (2.8 mmol as potassium carbonate) was added over 5 minutes, after which 2800.0 mmol (50.40 g) of water was added over 20 minutes. Here, no significant temperature increase occurred during the additions. Subsequently, a polycondensation reaction was performed under a nitrogen stream for 5 hours while the temperature was maintained at 50° C.

Next, the reaction solution was cooled, and simultaneously, 137.70 g of methyl isobutyl ketone and 100.60 g of a 5% saline solution were added thereto. The solution was transferred to a 1 L separation funnel, and then 137.70 g of methyl isobutyl ketone was again added, and rinsing with water was performed. After the separation, the water layer was removed, and the lower layer liquid was rinsed with water until the lower layer liquid became neutral. The upper layer liquid was then fractioned, after which the solvent was distilled away from the upper layer liquid at a pressure of 1 mmHg and a temperature of 50° C., and 75.18 g of a colorless, transparent liquid product (an epoxy group-containing low-molecular weight polyorganosilsesquioxane: silsesquioxane) containing 23 mass % of methyl isobutyl ketone was provided.

Note that when the product was analyzed, the number average molecular weight was found to be 2235, and the molecular weight dispersity was 1.54. A ratio [T3 form/T2 form] of T2 forms and T3 forms calculated from the ²⁹Si-NMR spectrum of the product was 11.9. The confirmation was performed through ¹H-NMR and ²⁹Si-NMR of the resulting epoxy group-containing low-molecular weight polyorganosilsesquioxane.

The molecular weight of the product was measured using the Shimadzu LC-20AD pump, the Shodex RI-504 detector, the Shodex GPC KF-602 and KF-603 columns, the Shodex GPC KF-G guard column, and THF as the solvent at a measurement temperature condition of 40° C. In addition, the ratio [T3 form/T2 form] of T2 forms and T3 forms in the product was measured through ²⁹Si-NMR spectrum measurements using the JEOL ECA500 (500 MHz).

### Preparation of Hard Coat Agent

The materials described in Table 1 were mixed with the above silsesquioxane at the constituent proportions shown in Table 1, and a hard coat agent was thereby prepared. The content proportions shown in Tables 1 to 7 are the blending proportions of the respective components. For the silsesquioxane (active component: 77 mass %) and RS-57 (active component: 20 mass %), the content proportions are the solution values, and for the other components, the content proportions are the values of the active component.

TABLE 1

| | | Constituent Proportion |
|---|---|---|
| | Material Name | (parts by mass) |
| Curable | Silsesquioxane | 65.6 |
| compound | 200PA-E5 | 1.5 |
| | Epolight 1600N | 4.5 |
| | Epolight 400E | 2.9 |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Example 1

As a primer, a product of the trade name “CELV B0955” (available from Daicel Corporation) was applied to a chemically reinforced ultra-thin glass (UTG) (available from Nippon Electric Glass Co., Ltd., 90 μm thick) to a thickness of 5 μm using a wire bar #5, and then cured by irradiation with ultraviolet rays at an illuminance of 300 mJ/cm² using a high-pressure mercury lamp. Next, a wire bar #30 was used to apply the hard coat agent onto the primer at an amount resulting in a thickness of 25 μm after curing of the hard coat agent, and then the coated UTG was placed in an oven at 80° C. for 1 minute and then in an oven at 120° C. for 2 minutes. Next, ultraviolet rays were irradiated thereon at an illuminance of 300 mJ/cm² using a high-pressure mercury lamp, and a hard coat layer was thereby formed. Subsequently, the resulting product was left in an oven at 120° C. for 60 minutes, and a transparent laminate of Example 1 was produced.

### Example 2

A transparent laminate of Example 2 was produced in the same manner as in Example 1 with the exception that a hard coat agent having a blending proportion described in Table 2 was used.

TABLE 2

| | | Constituent Proportion |
|---|---|---|
| | Material Name | (parts by mass) |
| Curable | Silsesquioxane | 65.6 |
| compound | 200PA-E5 | 1.5 |
| | Epolight 1600N | 2.0 |
| | Epolight 400E | 5.4 |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Example 3

A transparent laminate of Example 3 was produced in the same manner as in Example 1 with the exception that a hard coat agent having a blending proportion described in Table 3 was used.

TABLE 3

| | | Constituent Proportion |
|---|---|---|
| | Material Name | (parts by mass) |
| Curable | Silsesquioxane | 65.6 |
| compound | 200PA-E5 | 1.5 |
| | Epolight 1600N | 1.5 |
| | Epolight 400E | 5.9 |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Example 4

A transparent laminate of Example 4 was produced in the same manner as in Example 1 with the exception that a hard coat agent having a blending proportion described in Table 4 was used.

TABLE 4

| | | Constituent Proportion |
|---|---|---|
| | Material Name | (parts by mass) |
| Curable | Silsesquioxane | 65.6 |
| compound | 200PA-E5 | 1.5 |
| | Epolight 1600N | 1.2 |
| | Epolight 400E | 6.2 |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Example 5

A transparent laminate of Example 5 was produced in the same manner as in Example 1 with the exception that a hard coat agent having a blending proportion described in Table 5 was used.

TABLE 5

| | | Constituent Proportion |
|---|---|---|
| | Material Name | (parts by mass) |
| Curable | Silsesquioxane | 65.6 |
| compound | 200PA-E5 | 1.5 |
| | Epolight 1600N | 1.0 |
| | Epolight 400E | 6.4 |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Comparative Example 1

A transparent laminate of Comparative Example 1 was produced in the same manner as in Example 1 with the exception that a hard coat agent having a blending proportion descried in Table 6 was used.

TABLE 6

| | | Constituent Proportion |
|---|---|---|
| | Material Name | (parts by mass) |
| Curable | Silsesquioxane | 66.8 |
| compound | 200PA-E5 | 1.5 |
| | Epolight 1600N | 6.2 |
| | Epolight 400E | — |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Comparative Example 2

A transparent laminate of Comparative Example 2 was produced in the same manner as in Example 1 with the exception that a hard coat agent having a blending proportion described in Table 7 was used.

TABLE 7

| | | Constituent Proportion |
|---|---|---|
| | Material Name | (parts by mass) |
| Curable | Silsesquioxane | 65.6 |
| compound | 200PA-E5 | 1.5 |
| | Epolight 1600N | — |
| | Epolight 400E | 7.4 |
| Curing | Omnirad 127 | 0.2 |
| catalyst | Salt of triarylsulfonium and | 0.5 |
| | tetrapentafluorophenylgallium | |
| Antioxidant | ADK STAB AO-20 | 0.2 |
| Leveling agent | RS-57 | 0.4 |
| Solvent | MIBK | 8.4 |
| | MEK | 15.8 |

### Reference Example 1

The above-described UTG alone was used for evaluation as a Reference Example 1.

Each component listed in Tables 1 to 7 is described in detail below.
200PA-E5: a product of the trade name “Epoxy Ester 200PA-E5”, available from Kyoeisha Chemical Co., Ltd. (a compound having one or more cationically polymerizable functional groups and one or more radically polymerizable functional groups per molecule)
Epolight 1600N: a product of the trade name “Epolight 1600N”, available from Kyoeisha Chemical Co., Ltd. (an aliphatic compound having two or more cationically polymerizable groups per molecule), a short chain length compound B containing 1,6-hexanediol diglycidyl ether and having a functional group equivalent of from 140 to 160
Epolight 400E: a product of the trade name “Epolight 400E”, available from Kyoeisha Chemical Co., Ltd. (an aliphatic compound having two or more cationically polymerizable groups per molecule), a long chain length compound B containing nonaethylene glycol diglycidyl ether and having a functional group equivalent of from 264 to 290
Omnirad 127: a product of the trade name “Omnirad 127”, available from IGM Resins B. V. (a radical polymerization initiator)
A salt of triarylsulfonium and tetrapentafluorophenylgallium: a cationic polymerization initiator
ADK STAB AO-02: a product of the trade name “ADK STAB AO-02”, available from Adeka Corporation (an antioxidant)
RS-57: a product of the trade name “RS-57”, radically curable polyorganosiloxane not containing a compound corresponding to a PFAS, available from DIC Corporation (a leveling agent)
MIBK: Methyl isobutyl ketone (a solvent)
MEK: Methyl ethyl ketone (a solvent)

### Evaluation

The transparent laminates produced in the Examples and Comparative Examples and the glass substrate of the Reference Example were subjected to the following evaluations, and the results are shown in Table 8.

### (1) Microhardness Measurement

The hard coat layer surface of each of the transparent laminates produced in the Examples and Comparative Examples was measured at 10 points using a nanoindenter (trade name “ENT-2100”, available from Elionix Inc.) as a Berkovich indenter with a maximum load of 500 μN, and the average values of the indentation elastic modulus and the indentation hardness were determined. In addition, the ratio of the indentation elastic modulus to the indentation hardness (indentation elastic modulus/indentation hardness) was calculated from the average values of the indentation elastic modulus and the indentation hardness.

### (2) Pencil Hardness

The pencil hardness of the hard coat layer surface of each of the transparent laminates produced in the Examples and Comparative Examples was evaluated in accordance with JIS K5600-5-4 (750 g load).

### (3) Bendability

For each of the transparent laminates prepared in the Examples and Comparative Examples and the glass substrate of the Reference Example, a cylindrical mandrel bending tester (trade name “Bending Tester (cylindrical mandrel method)”, available from T P Giken K.K.) was used to measure, through the cylindrical mandrel method in accordance with JIS K5600-5-1 (1999), the bendability in a case in which the hard coat layer was oriented inward.

TABLE 8

| | | | | Compound (B) Ratio | | Microhardness Measurement | | |
|---|---|---|---|---|---|---|---|---|
| | | | Hard Coat | | Compound | | | Indentation |
| | Substrate | Undercoat | Layer | Short | Long Chain | Indentation | | Elastic |
| | Film | Layer Film | Film | Chain Compound | B | Elastic | Indentation | Modulus/ |
| | Thickness | Thickness | Thickness | B [parts by | [parts by | Modulus | Hardness | Indentation |
| No. | (μm) | (μm) | (μm) | mass] | mass] | (MPa) | (MPa) | Hardness |
| Reference | 90 | — | — | — | — | — | — | — |
| Example 1 | | | | | | | | |
| Example 1 | 90 | 5 | 25 | 4.5 | 2.9 | 3247 | 436 | 7.4 |
| Example 2 | 90 | 5 | 25 | 2 | 5.4 | 2510 | 313 | 8.0 |
| Example 3 | 90 | 5 | 25 | 1.5 | 5.9 | 1955 | 236 | 8.3 |
| Example 4 | 90 | 5 | 25 | 1.2 | 6.2 | 1300 | 151 | 8.6 |
| Example 5 | 90 | 5 | 25 | 1 | 6.4 | 873 | 98 | 8.9 |
| Comparative | 90 | 5 | 25 | 6.4 | — | 4472 | 760 | 5.9 |
| Example 1 | | | | | | | | |
| Comparative | 90 | 5 | 25 | — | 7.4 | 141 | 26 | 5.4 |
| Example 2 | | | | | | | | |

| | Pencil | Bendability |
|---|---|---|
| No. | Hardness | (mm) |
| Reference | — | 1.5 |
| Example 1 | | |
| Example 1 | 5H | 1.5 |
| Example 2 | 4H | 1.5 |
| Example 3 | 4H | 1.5 |
| Example 4 | 3H | 1.5 |
| Example 5 | 2H | 1.5 |
| Comparative | 7H | 2 |
| Example 1 | | |
| Comparative | <6B | 1.5 |
| Example 2 | | |

The transparent laminates of the Examples had a pencil hardness of H or higher, a minimum bendable radius of 1.5 mm or less when each of the transparent laminates is subjected to a cylindrical mandrel test with the hard coat layer side being concave, and a ratio of the indentation elastic modulus to the indentation hardness in the microhardness measurements of 6.0 or greater, and thereby transparent laminates having excellent bendability while maintaining a high hardness could be produced. On the other hand, when the ratio of the indentation elastic modulus to the indentation hardness in the microhardness measurement was less than 6.0, the results confirmed that the flexibility was inferior (Comparative Example 1) or the surface hardness was insufficient (Comparative Example 2).

Hereinafter, variations of the invention according to the present disclosure will be described.

### [Addendum 1]

A transparent laminate including:
a substrate; and
a hard coat layer laminated on at least one surface of the substrate,
wherein
the transparent laminate has a pencil hardness of H or higher at a load of 750 g on a surface of the hard coat layer,
the transparent laminate has a minimum bendable radius of 1.5 mm or less when the transparent laminate is subjected to a cylindrical mandrel test with the surface of the hard coat layer of the transparent laminate being concave, and
the transparent laminate has a ratio of an indentation elastic modulus to an indentation hardness (indentation elastic modulus/indentation hardness) of 6.0 or greater in a microhardness test.

### [Addendum 2]

The transparent laminate according to addendum 1, wherein the haze of the hard coat layer is 1.0% or less.

### [Addendum 3]

The transparent laminate according to addendum 1 or 2, wherein the hard coat layer is a cured product of a curable composition containing one or more curable compounds, and
the curable composition contains, as the one or more curable compounds, an aliphatic compound having two or more cationically polymerizable groups per molecule.

### [Addendum 4]

The transparent laminate according to addendum 3, wherein the composition contains, as the one or more curable compound, a polyorganosilsesquioxane.

### [Addendum 5]

The transparent laminate according to addendum 3 or 4, wherein the curable composition contains, as the one or more curable compound, two or more types of the aliphatic compound.

### [Addendum 6]

The transparent laminate according to any one of addenda 3 to 5, wherein the curable composition further contains a curing catalyst.

### [Addendum 7]

The transparent laminate according to addendum 6, wherein the curing catalyst includes a cationic polymerization initiator.

### [Addendum 8]

The transparent laminate according to addendum 6 or 7, wherein the curing catalyst includes a radical polymerization initiator.

### [Addendum 9]

The transparent laminate according to any one of addenda 1 to 8, wherein the hard coat layer does not contain a compound corresponding to a PFAS.

### [Addendum 10]

The transparent laminate according to any one of addenda 1 to 9, further including a surface protection film on at least one surface thereof.

### [Addendum 11]

The transparent laminate according to any one of addenda 1 to 10, wherein the hard coat layer is provided on one surface of the substrate, and a tacky adhesive layer is provided on the other surface of the substrate.

### [Addendum 12]

The transparent laminate according to any one of addenda 1 to 11, wherein the substrate is glass having a thickness of from 30 to 100 μm.

### [Addendum 13]

An image display device including the transparent laminate described in any one of addenda 1 to 12.

### [Addendum 14]

The image display device according to addendum 13, wherein the image display device is a flexible display.

### [Addendum 15]

The image display device according to addendum 13 or 14, wherein the image display device is an organic electroluminescence display device.

### [Addendum 16]

A flexible device including the image display device described in any one of addenda 13 to 15.

1. A transparent laminate comprising:
a substrate; and
a hard coat layer laminated on at least one surface of the substrate,
wherein
the transparent laminate has a pencil hardness of H or higher at a load of 750 g on a surface of the hard coat layer,
the transparent laminate has a minimum bendable radius of 1.5 mm or less when the transparent laminate is subjected to a cylindrical mandrel test with the surface of the hard coat layer of the transparent laminate being concave, and
the transparent laminate has a ratio of an indentation elastic modulus to an indentation hardness (indentation elastic modulus/indentation hardness) of 6.0 or greater in a microhardness test.

2. The transparent laminate according to claim 1, wherein a haze of the hard coat layer is 1.0% or less.

3. The transparent laminate according to claim 1, wherein the hard coat layer is a cured product of a curable composition comprising one or more curable compounds, and
the curable composition comprises, as the one or more curable compounds, an aliphatic compound having two or more cationically polymerizable groups per molecule.

4. The transparent laminate according to claim 3, wherein the curable composition comprises, as the one or more curable compounds, a polyorganosilsesquioxane.

5. The transparent laminate according to claim 3, wherein the curable composition comprises, as the one or more curable compounds, two or more types of the aliphatic compounds.

6. The transparent laminate according to claim 3, wherein the curable composition further comprises a curing catalyst.

7. The transparent laminate according to claim 6, wherein the curing catalyst comprises a cationic polymerization initiator.

8. The transparent laminate according to claim 6, wherein the curing catalyst comprises a radical polymerization initiator.

9. The transparent laminate according to claim 1, wherein the hard coat layer does not comprise a compound corresponding to a PFAS.

10. The transparent laminate according to claim 1, further comprising a surface protection film on at least one surface thereof.

11. The transparent laminate according to claim 1, wherein the hard coat layer is provided on one surface of the substrate, and a tacky adhesive layer is provided on the other surface of the substrate.

12. The transparent laminate according to claim 1, wherein the substrate is glass having a thickness of from 30 to 100 μm.

13. An image display device comprising the transparent laminate described in claim 1.

14. The image display device according to claim 13, wherein the image display device is a flexible display.

15. The image display device according to claim 13, wherein the image display device is an organic electroluminescent display device.

16. A flexible device comprising the image display device described in claim 13.
